(19) United States
(12) Patent Application Publication
(10) Pub. No.: US 2010/0055317 A1
(43) Pub. Date: Mar. 4, 2010

(54) FILM DEPOSITION APPARATUS EXPOSING SUBSTRATE TO PLURAL GASES IN SEQUENCE

(75) Inventors: HITOSHI KATO, Oshu-Shi (JP); Manabu Honma, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/549,590

(22) Filed: Aug. 28, 2009

(30) Foreign Application Priority Data
Sep. 4, 2008 (JP) 2008-227027

(51) Int. Cl. C23C 16/46; C23C 16/00

(52) U.S. Cl. 427/255.28; 118/724

(57) ABSTRACT

A film deposition apparatus for forming a thin film by supplying a first reactant gas and a second reactant gas in a vacuum container includes a rotation table, a first reactant gas supply unit and a second reactant gas supply unit extending radially at a first angular position and at a second angular position with respect to a rotation center, respectively, a first purge gas supply unit disposed at a third angular position between the first angular position and the second angular position, a first space having a first height in an area including the first angular position, a second space having a second height in an area including the second angular position, a third space disposed in an area including the third angular position having a height lower than the first height and the second height, and a heating unit configured to heat the first purge gas.

### BACKGROUND OF THE INVENTION

1. Field of the Invention

The disclosures herein generally relate to film deposition apparatuses, and particularly relate to a film deposition apparatus that supplies plural reactant gases to a substrate in sequence.

2. Description of the Related Art

A certain type of film deposition method used in semiconductor manufacturing processes repeats plural cycles each of which causes a first reactant gas to be adsorbed on the surface of a semiconductor wafer (hereinafter referred to as a “wafer”) serving as a substrate in vacuum atmosphere and then switches the supplied gas to a second reactant gas to form one or more layers of atoms or molecules through reaction of these two gases. The repetition of cycles creates layers one over another thereby to form a film on the substrate. Such a process is referred to as the ALD (Atomic Layer Deposition) or MLD (Molecular Layer Deposition). This process can control a film thickness with high precision by adjusting the number of cycles. High homogeneity of film quality over the extent of the surface is obtainable, thereby helping to create a thin semiconductor device.

Such a film deposition method may be preferred when forming a highly dielectric material for use as a gate oxide film, for example. When forming a silicon oxide film (i.e., SiO2 film), for example, bis-tertiary butyl amino silane (hereinafter referred to as “BTBAS”) may be used as a first reactant gas (i.e., source gas), and ozone gas may be used as a second reactant gas (i.e., oxidant gas).

Apparatuses for practicing the above-noted film deposition method may be configured such that a gas shower head is provided over a center area in a vacuum container. Reactant gases are caused to flow from above the center of a substrate, and the residual reactant gases and by-product materials are exhausted from the bottom of the process chamber. Such a film deposition method requires a lengthy time for gas replacement by use of a purge gas. Further, few hundred cycles may be necessary. The total process time can thus be very long. There is thus a demand for a film deposition apparatus and method that can achieve high throughput.

Against this background, a film deposition apparatus has been developed in which plural substrates are circularly arranged on a rotary table in a vacuum container for the film deposition process. The following describes some examples of such an apparatus.

Patent Document 1 discloses a film deposition apparatus which uses a flat cylindrical vacuum container that is divided into a first half and a second half. An exhaust outlet having a shape matching the semicircle outline of each half is provided in each of the first half and the second half to perform upward exhaust. An isolation area between the first semicircle outline and the second semicircle outline, i.e., an area along the diameter of the vacuum container, is provided with discharge ports for discharging a purge gas. Source gas supply stations are provided in the first and second semicircle areas, respectively, to supply different source gases. As a rotary table revolves inside the vacuum chamber, a workpiece passes through the first semicircle area, the isolation area, and the second semicircle area while the source gases are exhausted through the exhaust outlets. The ceiling of the isolation area where the purge gas is injected is positioned lower than the ceilings of the supply areas where the source gases are injected.

Patent Document 2 discloses a film deposition apparatus in which four wafers are arranged at equal distances from each other in a circular direction on a wafer support member (i.e., rotary table). First reactant-gas discharge nozzles and second reactant-gas discharge nozzles are situated in the circular direction at equal distances from each other to face the wafer support member, with purge nozzles situated therebetween. The wafer support member is configured to rotate horizontally. Each wafer is supported by the wafer support member. The surface of each wafer is elevated from the upper surface of the wafer support member by an elevation equal to the thickness of the wafer. The nozzles are arranged to extend radially with respect to the wafer support member. The distance between the nozzles and the wafers is set longer than 0.1 mm. Vacuum exhaustion is performed through a space between the outer circumference of the wafer support member and the inner wall of the process chamber. In this apparatus, an air curtain is formed below the purge gas nozzles, thereby preventing the first reactant gas and the second reactant gas from being mixed.

Patent Document 3 discloses a film deposition apparatus having a vacuum chamber which is partitioned by barrier walls into a plurality of process rooms in a circumferential direction, with a circular rotatable platform having a minute clearance from the lower end of the barrier walls. Wafers are arranged on the platform.

Patent Document 4 discloses a film deposition method that divides a circular gas supply plate into 8 sections in a circumferential direction, such that an AsH3 gas supply port, an H2 gas supply port, a TMG gas supply port, and an H2 gas supply port are arranged at a 90-degree angle relative to one another. Gas exhaust outlets are provided between these gas supply ports. A rotating susceptor for supporting wafers is situated to face the gas supply plate.

Patent Document 5 discloses a film deposition apparatus in which an area over a rotary table is partitioned by four vertical walls in a cross shape fashion, with wafers placed in the four partitioned placement areas. A source gas injector, a reactant gas injector, and a purge gas injector are alternately arranged in a circular direction to form a cross-shaped injector unit. The injector unit is horizontally rotated such that the injectors are placed in each of the four placement areas in sequence. Vacuum exhaust is performed from the periphery of the rotary table.

Patent Document 6 through 8 discloses an apparatus for performing an atomic layer CVD that causes gases to be alternately adsorbed to the target (e.g., wafer). In this apparatus, a susceptor for supporting wafers is rotated while a source gas and a purge gas are caused to flow from above the susceptor. Paragraphs 0023 through 0025 disclose a configuration in which barrier walls radially extend from the center of the chamber, and gas flow ports situated under the barrier walls supply a reactant gas or purge gas to the susceptor. Further, an inert gas is discharged from gas flow ports provided on the barrier walls to form a gas curtain. Exhaustion is disclosed in paragraph 0058. According to the disclosure, a source gas and a purge gas are exhausted through exhaust channels 30a and 30b, respectively.

With the film deposition apparatus and method disclosed in the above-noted patent documents, plural substrates are placed on a rotary table in a circular direction in a vacuum chamber to perform a film deposition process. The use of such an apparatus and method may encounter problems as follows.

In the film deposition apparatus and method disclosed in Patent Document 1, the upwardly directed exhaust outlet is provided between the purge gas discharge ports and the reactant gas supply area, and exhausts the reactant gas together with the purge gas. In such an arrangement, the reactant gas sprayed to a workpiece is sucked into the exhaust outlet as an upward flow to unsettle particles. This gives rise to the problem that wafer contamination by particles may likely occur.

In the film deposition apparatus and method disclosed in Patent Document 2, the air curtain created by the purge gas nozzle is not sufficiently effective because of the rotation of the wafer support member, so that the reactant gases on either side of the curtain may pass through the curtain. Especially, the gas originating upstream in the circular direction may be likely to disperse into the air curtain. Further, the first reactant gas discharged from the first reactant gas discharge nozzles may undesirably pass through the center area of the wafer support member serving as a rotary table to reach the second reactant gas area where the second reactant gas discharge nozzles are situated. When the first reactant gas and the second reactant gas are mixed on a wafer, reaction products are attached to the surface of the wafer. This gives rise to the problem that a satisfactory ALD (or MLD) process cannot be attained.

In the film deposition apparatus and method disclosed in Patent Document 3, the process gases disperse into adjacent rooms through gaps between the barrier walls and the platform or wafers. Further, since an exhaust station is provided between the process rooms, a gas originating from upstream and a gas originating from downstream may be mixed in the exhaust station when a wafer passes through the exhaust station. This gives rise to the problem that this apparatus cannot be used for the ALD film deposition method.

In the film deposition apparatus and method disclosed in Patent Document 4, no realistic mechanism is provided to isolate the two reactant gases. These two reactant gases may certainly be mixed around the center of the susceptor, and may also be mixed in non-center areas through places where the H2 gas supply ports are arranged. There is also a fatal problem in that the provision of an exhaust outlet facing the position at which a wafer passes may likely cause the wafer to be contaminated by particles due to the unsettling of particles from the surface of the susceptor.

In the film deposition apparatus and method disclosed in Patent Document 5, it takes a long time to replace the atmosphere of the placement area with a purge gas by use of the purge gas nozzles after the placement area is filled with a source gas or reactant gas. Further, there is a high possibility of having a source gas or reactant gas dispersing into an adjacent placement area through the vertical wall, resulting in the gases reacting in the adjacent placement area.

In the film deposition apparatus and method disclosed in Patent Documents 6 through 8, it is impossible to avoid the mixing of source gases in a purge gas compartment as these gases come from the adjacent source gas compartments. This gives rise to the problem that reaction products are generated to contaminate the wafers with particles.

Further, the film deposition apparatus and method disclosed in Patent Documents 1, 2, and 5 may perform film deposition while keeping the temperature of the substrate to a temperature higher than the room temperature. In such a case, when a reactant gas or purge gas staying at the room temperature is sprayed to the substrate, the substrate is cooled by the gas thereby to exhibit temperature variations. As a result, the adsorption and reaction of the reactant gas cannot be performed evenly over the extent of the substrate surface. This gives rise to the problem that a homogeneous thin film cannot be formed.

[Patent Document 1] U.S. Pat. No. 7,153,542

[Patent Document 2] Japanese Patent Application Publication No. 2001-254181

[Patent Document 3] Japanese Patent No. 3144664

[Patent Document 4] Japanese Patent Application Publication No. 4-287912

[Patent Document 5] U.S. Pat. No. 6,634,314

[Patent Document 6] Japanese Patent Application Publication No. 2007-247066

[Patent Document 7] United States Patent Application Publication No. 2007218701

[Patent Document 8] United States Patent Application Publication No. 2007218702

### SUMMARY OF THE INVENTION

A film deposition apparatus is provided to supply a plurality of reactant gases to react with each other to a surface of a substrate thereby to form a thin film made by disposing a plurality of layers comprised of reaction products.

In one embodiment, a film deposition apparatus for forming a thin film by exposing a substrate to at least two types of reactant gases including a first reactant gas and a second reactant gas in sequence in a vacuum container includes: a vacuum container having a top panel; a rotary table capable of rotating around a rotation center in the vacuum container and having one or more substrate placement parts on which substrates are placed; a first reactant gas supply unit and a second reactant gas supply unit extending radially at a first angular position and at a second angular position with respect to the rotation center, respectively, to supply the first reactant gas and the second reactant gas, respectively; a first purge gas supply unit extending radially at a third angular position between the first angular position and the second angular position to supply a first purge gas for isolating the first reactant gas and the second reactant gas from each other; a first lower surface area of the top panel situated at a first height from the rotary table to form a first space having the first height over the rotary table in at least part of an area that includes the first angular position; a second lower surface area of the top panel situated at a second height from the rotary table to form a second space having the second height over the rotary table in at least part of an area that includes the second angular position; a third lower surface area of the top panel situated at a third height from the rotary table to form a third space having the third height over the rotary table in at least part of an area that includes the third angular position, the third height being lower than the first height and the second height; a heating unit configured to heat the first purge gas; a second purge gas supply unit configured to supply a second purge gas to isolate the first reactant gas and the second reactant gas from each other in a center area including the rotation center; and exhaust outlets each configured to exhaust a corresponding one of the first reactant gas and the second reactant gas together with the first purge gas discharged from the third space and the second purge gas discharged from the center area.

In another embodiment, a film deposition method of forming a thin film on a substrate by exposing the substrate to at least two types of reactant gases including a first reactant gas and a second reactant gas in sequence in a vacuum container is provided. In the vacuum container a first purge gas supply area is provided to supply a first purge gas to isolate the first reactant gas and the second reactant gas from each other over a rotary table having the substrate placed thereon, and a height of a top panel of the vacuum container from an upper surface of the rotary table in the first purge gas supply area is lower than heights of the top panel in areas to which the first reactant gas and the second reactant gas are supplied, thereby to supply the first purge gas in a space having a relatively low height. In the vacuum container, further, a second purge gas is supplied to an area around a rotation center of the rotary table at a lower surface of the top panel to isolate the first reactant gas and the second reactant gas from each other, and each of the first reactant gas and the second reactant gas is exhausted together with the first purge gas and the second purge gas, so that the first reactant gas and the second reactant gas are supplied separately from each other to form a thin film. The method includes the steps of a placement step of placing substrates on the rotary table inside the vacuum container; a rotation step of rotating the rotary table; and a film forming step of heating the rotary table from below, supplying the first reactant gas and the second reactant gas from a first reactant gas supply unit and a second reactant gas supply unit, respectively, situated at different angular positions with respect to a rotation center of the rotary table, supplying the first purge gas from a first purge gas supply unit situated between the first reactant gas supply unit and the second reactant gas supply unit after heating the first purge gas, and moving the substrates in association with the rotation of the rotary table thereby repeating supplying the first reactant gas, stopping the first reactant gas, supplying the second reactant gas, and stopping the second reactant gas with respect to a surface of the substrate to form a thin film.

According to at least one embodiment, high throughput is achieved. Also, a satisfactory process is performed by preventing plural reactant gases from being mixed over the substrates. Further, the substrates are prevented from being cooled by a purge gas, thereby making it possible to form a homogeneous thin film.

### BRIEF DESCRIPTION OF THE DRAWINGS

FIG. 1 is a longitudinal sectional view illustrating the configuration of a film deposition apparatus according to a first embodiment;

FIG. 2 is an oblique perspective view schematically illustrating the configuration of the film deposition apparatus according to the first embodiment;

FIG. 3 is a plan view schematically illustrating the configuration of the film deposition apparatus according to the first embodiment;

FIGS. 4A and 4B are drawings illustrating the configuration of the film deposition apparatus according to the first embodiment, and provide a cross-sectional view of first through third spaces;

FIG. 5 is an oblique perspective view illustrating a first reactant gas supply unit of the film deposition apparatus according to the first embodiment;

FIG. 6 is a drawing schematically illustrating the configuration of a heater of the film deposition apparatus according to the first embodiment;

FIG. 7 is a longitudinal sectional view taken along a line A-A in FIG. 3 for illustrating a portion of the film deposition apparatus according to the first embodiment;

FIGS. 8A and 8B are a transverse sectional view and a longitudinal sectional view, respectively, for illustrating an example of the size of a third lower surface of the film deposition apparatus according to the first embodiment;

FIG. 9 is a longitudinal sectional view taken along the line B-B in FIG. 3 for illustrating the flows of a second purge gas, a third purge gas, and a fourth purge gas in the film deposition apparatus according to the first embodiment;

FIG. 10 is a partially sectional oblique view illustrating a portion of the film deposition apparatus according to the first embodiment;

FIG. 11 is a drawing schematically illustrating the configuration of a control unit of the film deposition apparatus according to the first embodiment;

FIG. 12 is a flowchart illustrating the steps of the method of forming a film by use of the film deposition apparatus according to the first embodiment;

FIG. 13 is a drawing illustrating the method of forming a film by use of the film deposition apparatus according to the first embodiment, with illustration of the flows of the first reactant gas, the second reactant gas, and the first purge gas;

FIG. 14 is a drawing schematically illustrating the configuration of a heater of the film deposition apparatus according to a first variation of the first embodiment;

FIG. 15 is a longitudinal sectional view schematically illustrating the configuration of the film deposition apparatus according to a second variation of the first embodiment;

FIG. 16 is a longitudinal sectional view schematically illustrating the configuration of the film deposition apparatus according to a third variation of the first embodiment;

FIG. 17 is a longitudinal sectional view illustrating another example of the shape of the top panel at the third lower surface part in the film deposition apparatus according to a fourth variation of the first embodiment;

FIGS. 18A through 18C are longitudinal sectional views illustrating other examples of the shape of the top panel at the third lower surface part in the film deposition apparatus according to a fifth variation of the first embodiment;

FIGS. 19A through 19C are base views illustrating examples of gas discharge ports of the first purge gas supply unit of the film deposition apparatus according to a sixth variation of the first embodiment;

FIGS. 19D through 19G are base views illustrating examples of the shape of the third lower surface part of the film deposition apparatus according to the sixth variation of the first embodiment;

FIG. 20 is a transverse sectional view schematically illustrating the configuration of a film deposition apparatus according to a seventh variation of the first embodiment;

FIG. 21 is a transverse sectional view schematically illustrating the configuration of a film deposition apparatus according to an eighth variation of the first embodiment;

FIG. 22 is an oblique perspective view schematically illustrating the configuration of the film deposition apparatus according to a ninth variation of the first embodiment;

FIG. 23 is a transverse sectional view schematically illustrating the configuration of a film deposition apparatus according to a tenth variation of the first embodiment;

FIG. 24 is a longitudinal sectional view schematically illustrating the configuration of the film deposition apparatus according to an eleventh variation of the first embodiment; and

FIG. 25 is a plan view illustrating the configuration of a substrate processing apparatus according to a second embodiment.

### DESCRIPTION OF THE PREFERRED EMBODIMENTS

In the following, embodiments for carrying out the present invention will be described by referring to the accompanying drawings.

### First Embodiment

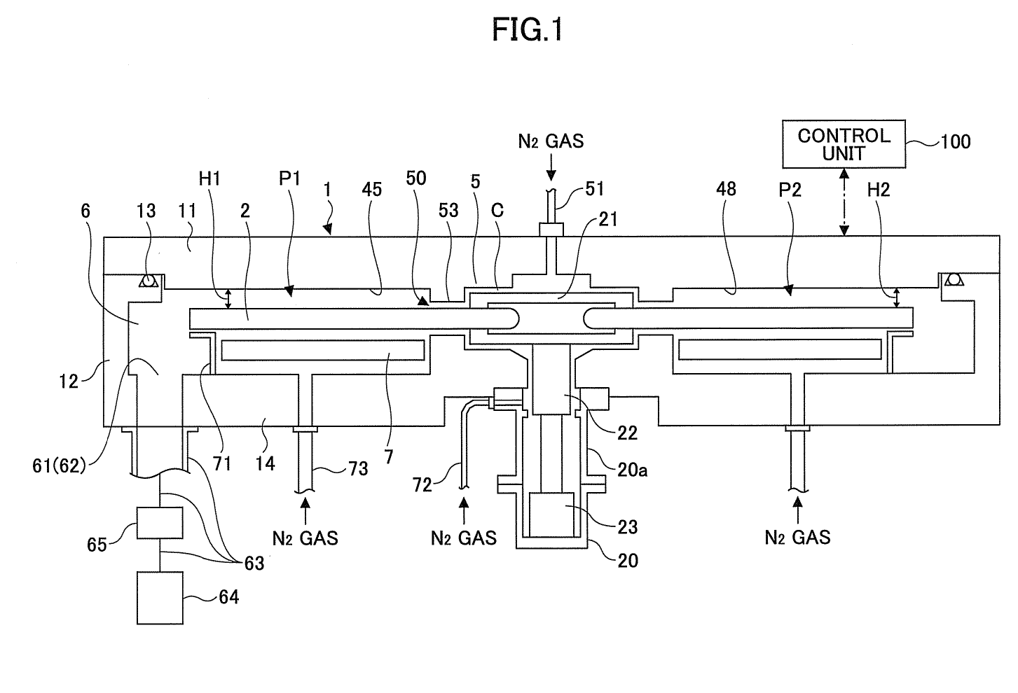

In the following, a description will be given of a film deposition apparatus and method according to a first embodiment by referring to FIG. 1 through FIG. 13.

A description will first be given of the configuration of the film deposition apparatus according to the present embodiment by referring to FIG. 1 through FIG. 11.

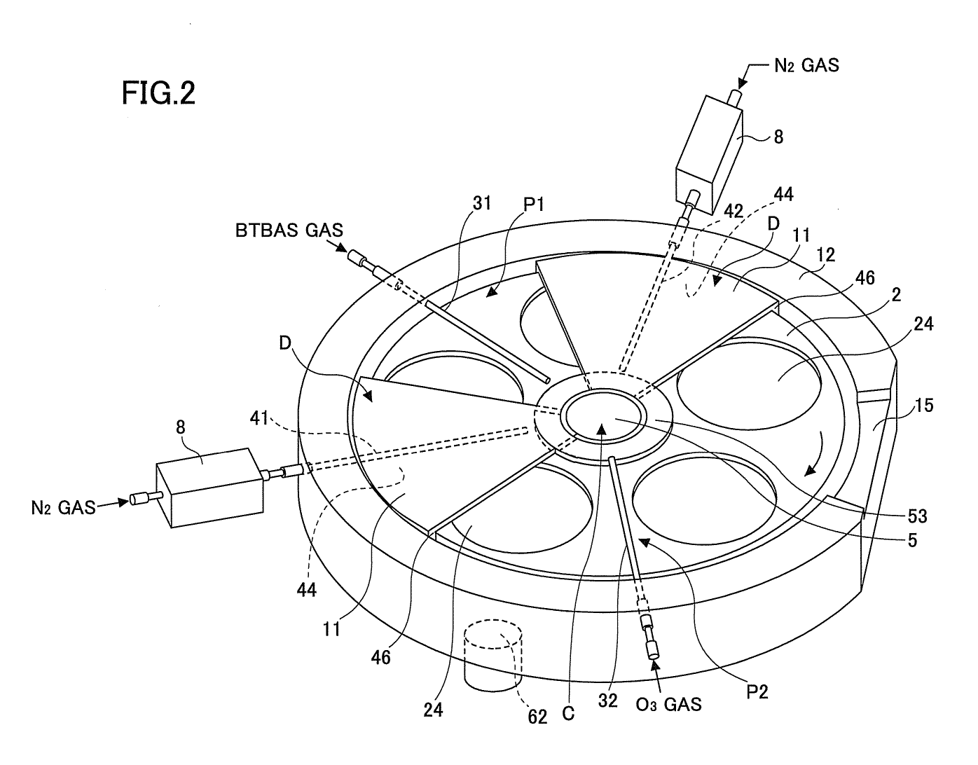

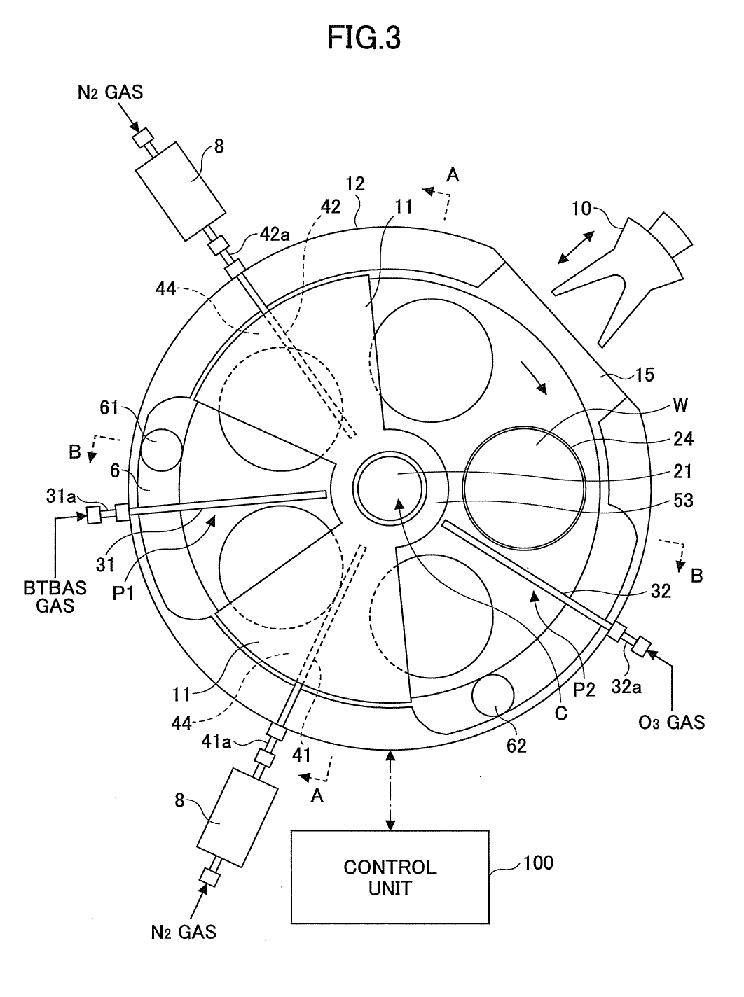

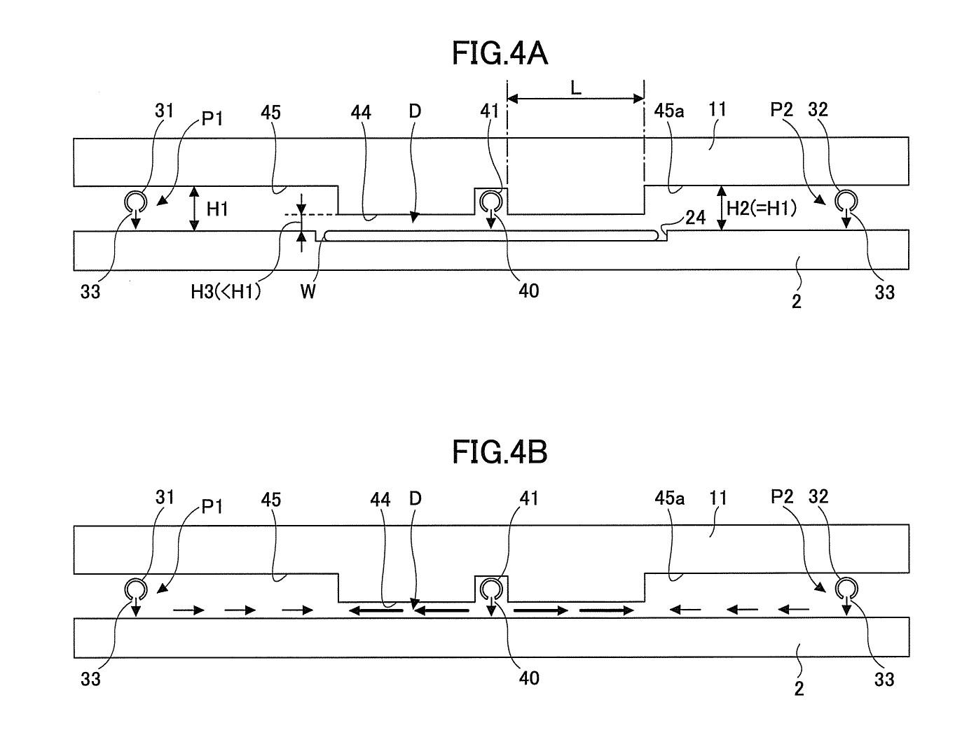

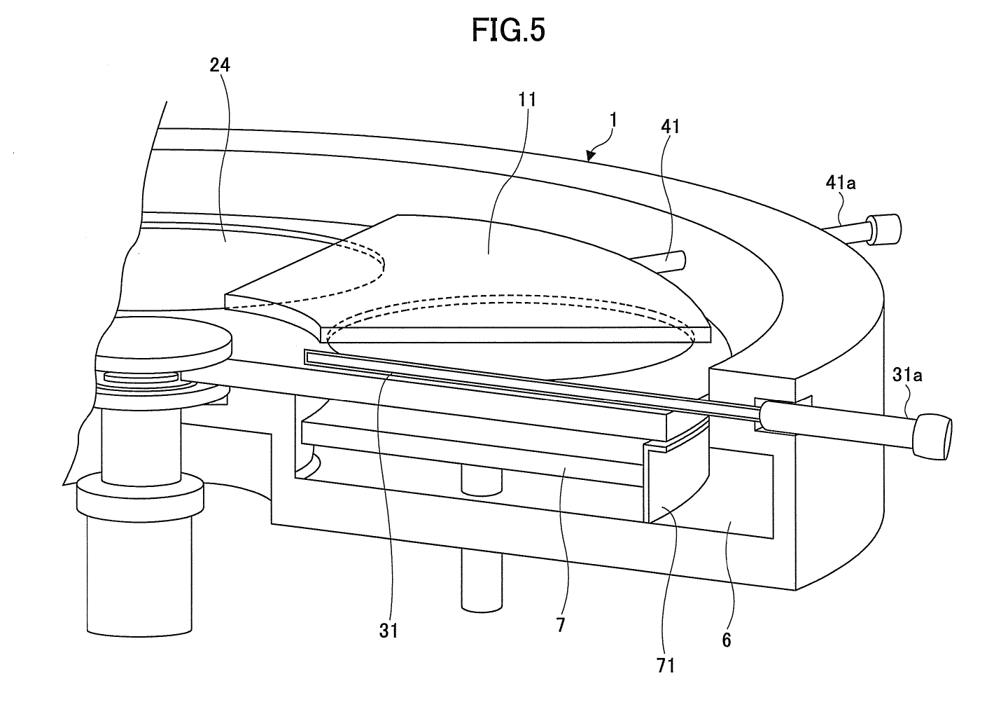

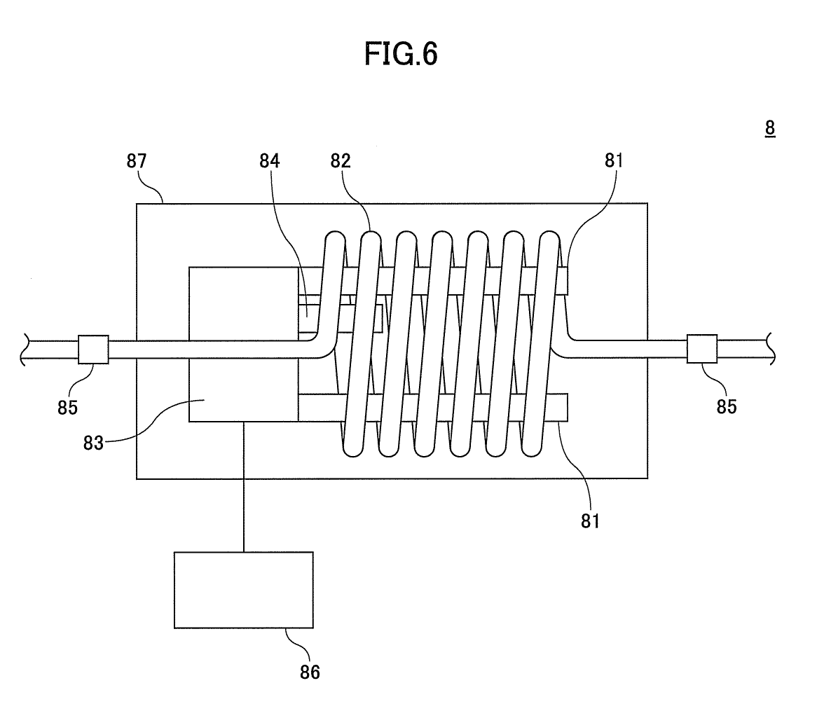

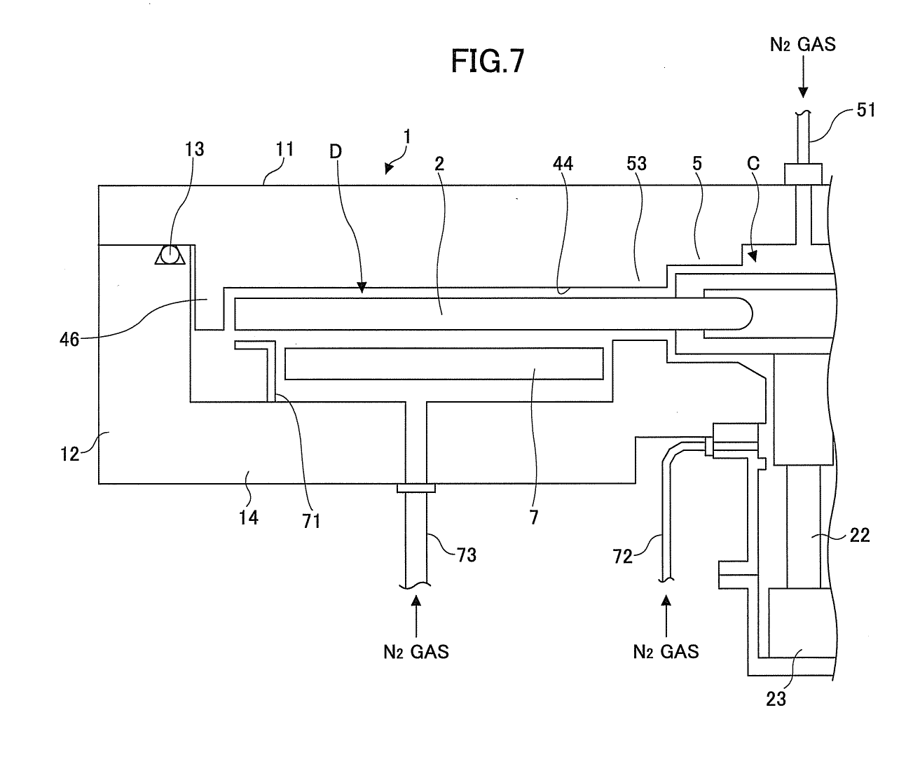

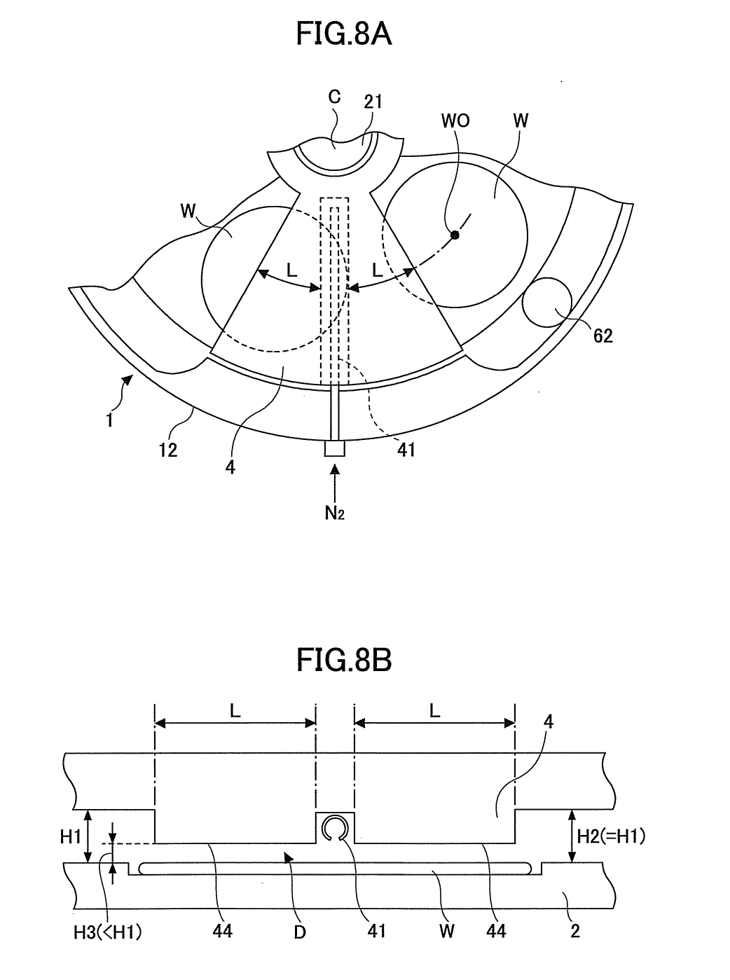

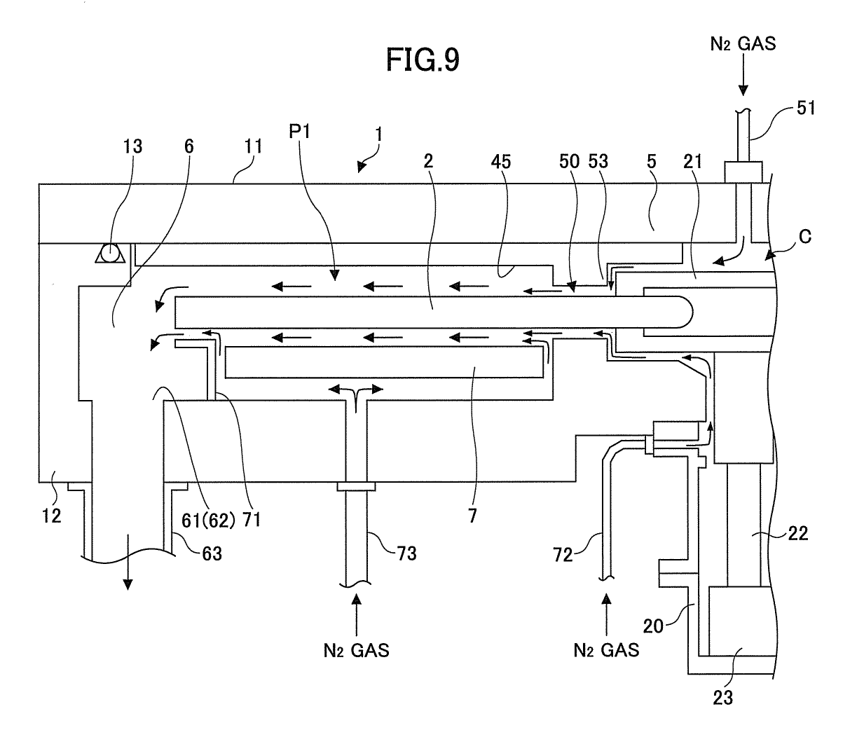

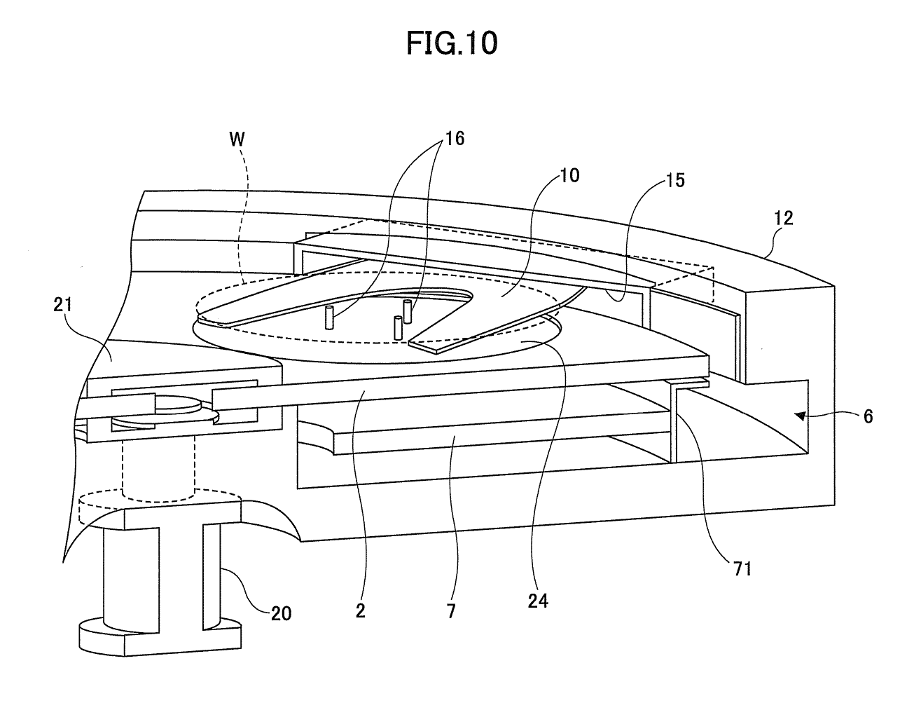

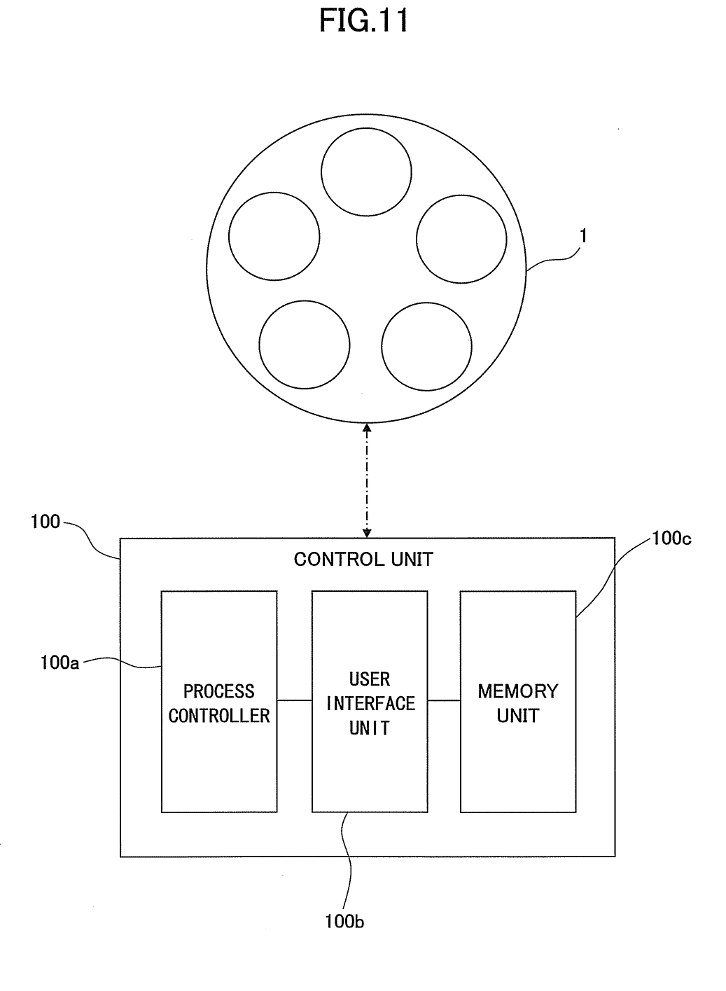

FIG. 1 is a longitudinal sectional view illustrating the configuration of the film deposition apparatus according to the present embodiment. The longitudinal sectional view illustrated in FIG. 1 is taken along a line B-B illustrated in FIG. 3. FIG. 2 is an oblique perspective view schematically illustrating the configuration of the film deposition apparatus according to the present embodiment. FIG. 3 is a plan view schematically illustrating the configuration of the film deposition apparatus according to the present embodiment. FIGS. 4A and 4B are drawings illustrating the configuration of the film deposition apparatus according to the present embodiment, and provide a cross-sectional view of first through third spaces. FIGS. 4A and 4B are development views in which a rotary table and the structure situated above the rotary table are sectioned along a concentric circle and developed in a horizontal direction. FIG. 5 is an oblique perspective view illustrating a first reactant gas supply unit of the film deposition apparatus according to the present embodiment. FIG. 6 is a drawing schematically illustrating the configuration of a heater of the film deposition apparatus according to the present embodiment. FIG. 7 is a longitudinal sectional view taken along a line A-A in FIG. 3 for illustrating a portion of the film deposition apparatus according to the present embodiment. FIGS. 8A and 8B are a transverse sectional view and a longitudinal sectional view, respectively, for illustrating an example of the size of a third lower surface of the film deposition apparatus according to the present embodiment. FIG. 9 is a longitudinal sectional view taken along the line B-B in FIG. 3 for illustrating the flows of a second purge gas, a third purge gas, and a fourth purge gas in the film deposition apparatus according to the present embodiment. FIG. 10 is a partially sectional oblique view illustrating a portion of the film deposition apparatus according to the present embodiment. FIG. 11 is a drawing schematically illustrating the configuration of a control unit of the film deposition apparatus according to the present embodiment.

As illustrated in FIG. 1 through FIG. 3, the film deposition apparatus according to the present embodiment includes a vacuum container 1, a rotary table 2, a first reactant gas supply unit 31, a second reactant gas supply unit 32, first purge gas supply units 41 and 42, and heating units 8.

The vacuum container 1 has a flat shape having an approximately circular outline as viewed from above. The vacuum container 1 includes a top panel 11, a container 12, an O ring 13, and a bottom section 14.

The top panel 11 is configured to be separable from the container 12. The top panel 11 is pressed against the container 12 due to reduced interior pressure, with the O ring 13 intervening therebetween to serve as a sealant, thereby maintaining the airtight condition. When disconnecting the top panel 11 from the container 12, a manipulation mechanism (not shown) is used to lift the top panel 11.

In the following, a description will be given of the top panel 11, the rotary table 2, and the structures situated below the top panel 11 and above the rotary table 2 among the various portions of the vacuum container 1. Namely, a description will be given of the rotary table 2, the first reactant gas supply unit 31, the second reactant gas supply unit 32, the first purge gas supply units 41 and 42, the heating units 8, the top panel 11, and a second purge gas supply unit 51.

The rotary table 2 is placed such as to have its rotational center at the center of the vacuum container 1 as illustrated in FIG. 1. The rotary table 2 includes a case 20, a core 21, a rotation shaft 22, a drive unit 23, and recesses 24.

The rotary table 2 is fixed at its center to the core 21 having a cylindrical shape. The core 21 is fixedly mounted to the top end of the rotation shaft 22 that vertically extends. The rotation shaft 22 penetrates through the bottom section 14 of the vacuum container 1, and has its bottom end attached to the drive unit 23. The drive unit 23 rotates the rotation shaft 22 clockwise around a vertical axis. The rotation shaft 22 and the drive unit 23 are accommodated in the case 20 having a cylindrical shape with an opening at the top. The case 20 has a flange portion at the top, which is attached to the bottom surface of the bottom section 14 of the vacuum container 1 in an airtight manner. The atmosphere inside the case 20 is thus hermetically isolated from the exterior atmosphere.

The recesses 24 are formed in the surface of the rotary table 2 as illustrated in FIG. 2 and FIG. 3, so that substrate wafers (i.e., five wafers in the illustrated example) can be placed therein in a circular direction (i.e., circumferential direction). The recesses 24 may have a circular shape. The recesses 24 serve to position wafers in order to prevent them from being thrown outwardly by a centrifugal force associated with the rotation of the rotary table 2. For the sake of convenience of illustration, FIG. 3 shows only one wafer W in one of the recesses 24.

As illustrated in FIG. 4A, the diameter of the recess 24 is slightly larger than the diameter of the wafer, e.g., larger by a margin of 4 mm, and the depth of the recess 24 is configured to be substantially equal to the thickness of the wafer. When the wafer is placed in the recess 24, thus, the upper surface of the wafer and the upper surface of the rotary table 2 (i.e., in the places where no wafer is placed) are flush with each other. If there is a large difference in elevation between the surface of the wafer and the surface of the rotary table 2, a step created by such a difference causes a pressure variation. For the purpose of achieving an even film thickness over the extent of the surface, the surface of the wafer and the surface of the rotary table 2 may preferably have the same elevation (i.e., flush with each other). The provision that the wafer surface and the surface of the rotary table 2 may preferably be flush with each other may include a situation in which the surface of the wafer (i.e., substrate) placed in the recess 24 (i.e., substrate placement part) is at the same elevation as the surface of the rotary table 2, and also a situation in which the surface of the wafer is actually slightly lower than the surface of the rotary table 2. It is preferable, however, that a difference in elevation between these surfaces be set as close to zero as processing precision allows. The difference may preferably be smaller than 5 mm. Through-holes are formed at the bottom surface of the recesses 24, so that three elevating pins are inserted through the through-holes for the purpose of elevating the wafer from the bottom surface of the wafer, as will be described by referring to FIG. 10.

The substrate placement part is not limited to a recess. Alternatively, guide members for embracing the circumferential edge of the wafer may be arranged on the rotary table 2 in a circular direction. Alternatively, the rotary table 2 may be provided with a chuck mechanism such as an electrostatic chuck. When a chuck mechanism is provided in the rotary table 2 to achieve wafer adhesion, the places to which wafers are adhered serve as the substrate placement parts.

The first reactant gas supply unit 31, the second reactant gas supply unit 32, and the two first purge gas supply units 41 and 42 are provided to face the recesses 24 formed in the rotary table 2 for the purpose of supplying the first reactant gas and the second reactant gas as illustrated in FIG. 2 and FIG. 3. The first reactant gas supply unit 31, the second reactant gas supply unit 32, and the two first purge gas supply units 41 and 42 extend radially at different angular positions around the rotation center, i.e., they extend from different points on the periphery of the vacuum container 1 (i.e., the periphery of the rotary table 2) toward the rotation center. Each of the first reactant gas supply unit 31, the second reactant gas supply unit 32, and the first purge gas supply units 41 and 42 is a nozzle along which spouts for downwardly discharging gas are formed at intervals in its longitudinal direction.

The first reactant gas supply unit 31, the second reactant gas supply unit 32, and the first purge gas supply units 41 and 42 may be attached to the sidewall of the vacuum container 1, such that gas injecting ports 31a, 32a, 41a, and 42a provided at the respective ends are situated outside the sidewall. In the present embodiment, the gas injecting ports 31a, 32a, 41a, and 42a are situated such as to introduce gases through the sidewall of the vacuum container 1 as partially illustrated in FIG. 5. Alternatively, these gas injecting ports may be situated such as to introduce gases through a circular projection 53. In such a case, an L-letter-shape pipe having an orifice on the outer circumferential surface of the projection 53 and another orifice on the outer surface of the top panel 11 may be provided. Each of the first reactant gas supply unit 31, the second reactant gas supply unit 32, and the first purge gas supply units 41 and 42 may be attached to the office of a corresponding pipe inside the vacuum container 1, and a corresponding one of the gas injecting ports 31a, 32a, 41a, and 42a may be attached to the orifice of the pipe outside the vacuum container 1.

With respect to each of the first reactant gas supply unit 31 and the second reactant gas supply unit 32, spouts 33 for downwardly discharging a reactant gas as illustrated in FIG. 4A and 4B are formed along the nozzle at intervals in its longitudinal direction. In the present embodiment, spouts having a diameter of 0.5 mm and downwardly facing are formed at 10-mm intervals along the extent of the gas nozzle constituting either the first reactant gas supply unit 31, or the second reactant gas supply unit 32, for example.

With respect to each of the first purge gas supply units 41 and 42, spouts 40 for downwardly discharging a purge gas as illustrated in FIG. 4A and 4B are formed along the nozzle at intervals in its longitudinal direction. In the present embodiment, spouts having a diameter of 0.5 mm and downwardly facing are formed at 10-mm intervals along the extent of the gas nozzle constituting either one of the first purge gas supply units 41 and 42.

The first reactant gas supply unit 31 and the second reactant gas supply unit 32 are coupled to a first reactant gas supply source and a second reactant gas supply source situated outside the vacuum container 1. The first purge gas supply units 41 and 42 are coupled to a first purge gas supply source situated outside the vacuum container 1. In the present embodiment, the second reactant gas supply unit 32, the first purge gas supply unit 41, the first reactant gas supply unit 31, and the first purge gas supply unit 42 are arranged clockwise in the order listed.

The heating units 8 are coupled to the gas injection ports 41a and 42a of the first purge gas supply units 41 and 42, respectively, outside the vacuum container 1 as illustrated in FIG. 2 and FIG. 3. The heating units 8 serve to heat the first purge gas and the second purge gas.

As illustrated in FIG. 6, each heating unit 8 includes a heater 81, a heating pipe 82, a thermo switch 83, a temperature sensor 84, a joint 85, an external power supply 86, and a base 87.

The heater 81 is a resistance heating element utilizing a resistor for generating heat. The heater 81 is not limited to any particular structure as long as it is a resistance heat generator. For example, the heater 81 may be a sheathed heater or a carbon heater. In the present embodiment, a sheathed heater is used as illustrated in FIG. 6.

The heating pipe 82 is a coil-shaped pipe circulating around the heater 81. The heating pipe 82 exchanges heat with the heater 81 while having the first purge gas flowing inside its interior space, thereby heating the first purge gas. The heating pipe 82 is not limited to any particular structure. For example, the heater 81 may be a SUS316 pipe having a ⅛-inch diameter.

The thermo switch 83, the temperature sensor 84, and the external power supply 86 serve to function as follows. The thermo switch 83 switches between the ON state and the OFF state in response to a difference between a preset temperature and a temperature measured by the temperature sensor 84. The external power supply 86 supplies power to the heater 81 when the thermo switch 83 is in the ON state. The heating units 8 as described above are used to heat the first purge gas. When the first purge gas supply units supply the first purge gas, thus, the cooling of temperature of the rotary table 2 and the substrates placed on the rotary table 2 is avoided.

In the present embodiment, the heating units 8 are situated outside the vacuum container 1. The positions of the heating units 8 are not limited to outside the vacuum container 1 as long as the first purge gas and second purge gas can be heated and supplied through the first purge gas supply units 41 and 42. Provision may be made such that the heating units 8 are situated inside the vacuum container 1.

In the present embodiment, the heating units 8 are provided at two separate locations corresponding to the first purge gas supply units 41 and 42, respectively. The heating units 8 may be positioned at the same location as long as the first purge gas and second purge gas can be heated and supplied through the first purge gas supply units 41 and 42.

In the present embodiment, BTBAS (bis-tertiary butyl amino silane) gas may be used as the first reactant gas. Further, O3 (ozone) gas may be used as the second reactant gas. N2 (nitrogen) gas may be used as the first purge gas. The first purge gas is not limited to N2 gas, and may be an inert gas such as Ar. The first purge gas is not even limited to an inert gas, and may be hydrogen gas, for example. As long as the gas does not affect the film deposition process, any type of gas may be used as the first purge gas.

The lower surface of the top panel 11 include a first lower surface part (first lower surface area) 45, a second lower surface part (second lower surface area) 45a, and third lower surface parts (third lower surface areas) 44, as illustrated in FIG. 2 through FIGS. 4A and 4B. The first lower surface part 45 is a surface situated at a distance H1 from the upper surface of the rotary table 2. The second lower surface part 45a is a surface situated at a distance H2 from the upper surface of the rotary table 2. Each of the third lower surface parts 44 is formed between the first lower surface part 45 and the second lower surface part 45a, and is a surface situated at a distance H3 from the upper surface of the rotary table 2. The lower surface of the top panel 11 further includes the projection 53 and a rotation center part 5. The projection 53 is situated alongside the first lower surface part 45 and the second lower surface part 45a on the side closer to the rotation center. The rotation center part 5 is at the position corresponding to the core 21.

The first lower surface part 45, the second lower surface part 45a, and the third lower surface part 44 are the lower surface areas of the top panel 11 that include the positions of the first reactant gas supply unit 31, the second reactant gas supply unit 32, and the first purge gas supply unit 41, respectively. The third lower surface part 44 is divided into two portions by the first purge gas supply unit 41.

As illustrated in FIG. 2 through FIGS. 4A and 4B, the lower surface areas of the top panel 11 corresponding to the first lower surface part 45, the second lower surface part 45a, and the two third lower surface parts 44 form a first space P1, a second space P2, and two third spaces D, respectively, together with the rotary table 2.

The first lower surface part 45 of the top panel 11 is the lower surface area of the top panel 11 that includes the position of the first reactant gas supply unit 31, as illustrated in FIGS. 4A and 4B. The second lower surface part 45a of the top panel 11 is the lower surface area of the top panel 11 that includes the position of the second reactant gas supply unit 32, as illustrated in FIGS. 4A and 4B. The third lower surface parts 44 of the top panel 11 are the lower surface areas of the top panel 11 that include the positions of the first purge gas supply units 41 and 42, respectively, as illustrated in FIGS. 4A and 4B. The distances from the center axis of the first purge gas supply unit 41 (or 42) to the opposite edges of the third lower surface part 44 having a fan shape are set equal to each other in the circular direction of the rotary table 2.

The third lower surface part 44 of the top panel 11 situated on the upstream side of the first purge gas supply unit 41 (or 42) in the rotation direction may have a width that is wider toward the periphery of the rotary table 2. When the rotary table 2 revolves, the closer to the periphery of the rotary table 2, the faster the flow of gas from upstream toward the third lower surface part 44 is. In the present embodiment, the wafer W has a diameter of 300 mm. The length of the third lower surface part 44 in the circumferential direction (i.e., the length of an arc that is part of a circle concentric to the rotary table 2) is 146 mm at a distance of 140 mm from the rotation center in the proximity of the projection 53. This length is 502 mm at the outermost position of the recesses 24 (i.e., substrate placement parts). As illustrated in FIG. 4A, the portion of the third lower surface part 44 of the top panel 11 situated on either side of the first purge gas supply unit 41 (42) has a length L in the circumferential direction that is equal to 246 mm at the above-noted outermost position.

The first lower surface part 45 of the top panel 11 that covers the position of the first reactant gas supply unit 31 is situated at a first height H1 from the rotary table 2 as illustrated in FIG. 1 and FIG. 4A. The second lower surface part 45a of the top panel 2 that covers the position of the second reactant gas supply unit 32 is situated at a second height H2 from the rotary table 2 as illustrated in FIG. 1 and FIG. 4A. The third lower surface part 44 of the top panel 1 that covers the position of the first purge gas supply unit 41 is situated at a third height H3 from the rotary table 2 as illustrated in FIG. 4A. The third height H3 is lower than the first height H1 and the second height H2. The relative size of the first height H1 in comparison with the second height H2 is not limited to any particular value. H1 may be set equal to H2, for example. In the present embodiment, thus, H3<H1=H2.

As illustrated in FIG. 4A, the third lower surface part 44 of the top panel 11 is situated on both sides of the first purge gas supply unit 41 in the circular direction, and has a surface at the third height H3 from the rotary table 2. Further, the first lower surface part 45 and the second lower surface part 45a higher than the third lower surface part 44 are situated on both sides of the third lower surface part 44 in the circular direction, respectively. In other words, the third space D is in existence on the both sides of the first purge gas supply unit 41 in the circular direction, and the first space P1 and the second space P2 are in existence on the both sides of the third space D in the circular direction, respectively. By the same token, another third space D is in existence between the first space P1 and the second space P2 on the other side of the circle.

The periphery of the top panel 11 (i.e., periphery of the vacuum container 1) corresponding to a third space D has a bent part 46 having an L-letter shape facing the side edge of the rotary table 2, as illustrated in FIG. 7. Since the top panel 11 can be disconnected from the container 12, the outer circumferential surface of the bent part 46 and the container 12 have a small gap therebetween. Similar to the third lower surface part 44, the bent part 46 is provided for the purpose of preventing the first reactant gas and the second reactant gas from being mixed. A gap between the inner circumferential surface of the bent part 46 and the side edge of the rotary table 2 as well as a gap between the outer circumferential surface of the bent part 46 and the container 12 are set to a similar size to the height H3 provided for the third lower surface part 44 relative to the surface of the rotary table 2. With respect to the surface of the rotary table 2, the inner circumferential surface of the bent part 46 provides a similar function to the inner circumferential surface of the vacuum container 1.

FIG. 2 and FIG. 3 illustrate views that would be obtained by horizontally cutting the top panel 11 of the vacuum container 1 at a height lower than the first lower surface part 45 and the second lower surface part 45a and higher than the first purge gas supply units 41 and 42.

In the following, a description will be given of the isolation function of the third space D to isolate the atmosphere of the first space P1 and the atmosphere of the second space P2 from each other. Also, a description will be given of the function to prevent wafers from being cooled by the purge gas so that a homogeneous thin film can be formed as a result of the absence of wafer temperature variation.

The third lower surface part 44 together with the first purge gas supply unit 41 (or 42) prevent the first reactant gas and the second reactant gas from intruding into the third space D, thereby preventing the mixing of the first reactant gas and the second reactant gas. Namely, the second reactant gas is prevented from entering the third space D by flowing in the counter-rotation direction of the rotary table 2, and the first reactant gas is prevented from entering the third space D by flowing in the rotation direction of the rotary table 2. Due to the prevention of gas intrusion, the first purge gas discharged from the first purge gas supply unit 41 spreads into the third space D to come out in the second space P2 that is situated under the adjacent second lower surface part 45a, so that the gas originating in the second space P2 cannot enter the third space D. The same also applies in the case of the first space P1. The prevention of gas intrusion not only means a situation in which the gases originating in the first space P1 and in the second space P2 cannot enter the third space D, but also means a situation in which gas intrusion occurs but the first reactant gas and the second reactant gas are not mixed in the third space D. As long as these conditions are maintained, the third space D properly achieves its purpose to isolate the atmosphere of the first space P1 and the atmosphere of the second space P2 from each other. It should be noted that a gas adsorbed to a wafer passes through the third space D. The gas that is referred to in the expression “prevention of gas intrusion” is one that is in the gas phase.

The height H3 of the third lower surface part 44 of the top panel 11 relative to the rotary table 2 illustrated in FIG. 4A may range from about 0.5 mm to about 10 mm, and may preferably be about 4 mm. In this case, the rate of revolution of the rotary table 2 may be set equal to 1 rpm to 500 rpm, for example. In order to secure the isolation function of the third lower surface part 44, the size of the third lower surface part 44 and the height H3 of the third lower surface part 44 relative to the rotary table 2 may be determined based on results obtained by conducting experiments, depending on the range of rate of revolution of the rotary table 2. As the first purge gas, not only N2 gas but also an inert gas such as Ar gas may be used. The first purge gas is not limited to an inert gas, and may even be hydrogen gas. As long as the gas does not affect the film deposition process, any type of gas may be used as the first purge gas.

In FIGS. 8A and 8B illustrating the first purge gas supply unit 41 as a representative, the third lower surface part 44 that forms a narrow space on either side of the first purge gas supply unit 41 (or 42) may preferably have a length L of 50 mm in the circular direction of the rotary table 2 at the position where the center WO of the wafer W passes when the wafer W used as a substrate to be processed has a diameter of 300 mm, for example. It is preferable to effectively prevent reactant gases from intruding from the sides of the third lower surface part 44 into the third space D (i.e., a narrow space having the third height H3 lower than the first height H1 and the second height H2) formed under the third lower surface part 44. To this end, the third height H3 that is the distance between the third lower surface part 44 and the rotary table 2 may be decreased if the length L is decreased. The third height H3 that is the distance between the third lower surface part 44 and the rotary table 2 may be set to a certain size. The speed of the rotary table 2 is higher toward the periphery of the rotary table 2. Accordingly, the length L required to sufficiently prevent the intrusion of reactant gases increases as its radial position moves away from the rotation center. In consideration of this, if the length L at the position where the center WO of the wafer W passes is smaller than 50 mm, the third height H3 that is the distance between the third lower surface part 44 and the rotary table 2 may need to be significantly reduced. Accordingly, a mechanism may need to be devised to suppress the fluctuation of the rotary table 2 such that the rotating rotary table 2 or the wafer W does not come in contact with the third lower surface part 44. The higher the rate of rotation of the rotary table 2, the more likely the reactant gases intrude into the space under the third lower surface part 44 from the upstream side of the third lower surface part 44. The use of the length L that is shorter than 50 mm may not be preferable in terms of throughput because such an arrangement requires the rate of rotation to be decreased. It is thus preferable to use the length L that is longer than 50 mm. It should be noted, however, that the size of the third lower surface part 44 is not limited to the above-noted example, and may be adjusted according to the process parameters and wafer size that are actually used. As is apparent from the above description, the height of the narrow space (i.e., the third height H3 of the third space D) may be adjusted in response to the size of the third lower surface part 44 as well as according to the process parameters and wafer size that are actually used. Such a height of the narrow space (i.e., the third space), however, needs to provide a sufficient space that transmits the purge gas from the third space D to the first or second space P1 or P2.

As illustrated in FIG. 1, the projection 53 of the top panel 11 is situated between the outer circumference of the core 21 and the first lower surface part 45 and between the outer circumference of the core 21 and the second lower surface part 45a. The projection 53 is opposed to the rotary table 2. Moreover, as illustrated in FIG. 7, the projection 53 of the top panel 11 is formed as an integrated unitary structure together with the third lower surface part 44 on the side near the rotation center. The lower surface of the projection 53 is flush with the surface of the third lower surface part 44. The projection 53 of the top panel 11 and the third lower surface part 44 do not have to be integrated, and may be separate from each other.

The rotation center part 5 of the top panel 11 is situated on the same side of the projection 53 as the side where the rotation center is situated. In the present embodiment, the boundary between the rotation center part 5 and the projection 53 may be positioned on a circumference having a radius of 140 mm around the rotation center.

The second purge gas supply unit 51 penetrates through the top panel 11 of the vacuum container 1 as illustrated in FIG. 1 and FIG. 7 to be connected to the center part of the vacuum container 1. The second purge gas supply unit 51 serves to supply a second purge gas to a center area C that is a space between the top panel 11 and the core 21. Although the second purge gas is not limited to any particular gas, N2 gas may be used.

The second purge gas supplied to the center area C flows through a narrow gap 50 between the projection 53 and the rotary table 2 toward the surface of the rotary table 2 where the substrate placement parts are provided, and further flows toward the periphery of the rotary table 2. Since the space enclosed by the projection 53 is filled with the second purge gas, the first reactant gas and the second reactant gas cannot be mixed with each other through the center portion of the rotary table 2 situated between the first space P1 and the second space P2. Namely, the film deposition apparatus is provided with the center area C that is partitioned by the center portion of the rotary table 2 and the vacuum container 1, and that discharges the supplied second purge gas to the surface of the rotary table 2 through a circumferential spout gap for the purpose of isolating atmospheres between the first space P1 and the second space P2. Here, the above-noted spout gap refers to the narrow gap 50 situated between the projection 53 and the rotary table 2.

As the rotary table 2 rotates, wafers placed on the rotary table 2 pass through the third space D provided for the purpose of isolating the first reactant gas and the second reactant gas from each other. The height of the third lower surface part 44 relative to the rotary table 2 in the third space D is lower than the height of the first lower surface part 45 relative to the rotary table 2 in the first space P1 and also lower than the height of the second lower surface part 45a relative to the rotary table 2 in the second space P2. Accordingly, the first purge gas discharged from the first purge gas supply unit 41 or 42 is likely to be directly sprayed to the rotary table 2 and to the wafers placed on the rotary table 2, compared with the first reactant gas in the first space P1 and the second reactant gas in the second space P2.

The rotary table 2 rotates while the rotary table 2 and the wafers thereon are heated to a predetermined temperature by a heater unit 7, as will be described later. The temperature of the rotary table 2 and the wafers does not noticeably change when the rotary table 2 and the wafers pass through the first space P1 or the second space P2. When the rotary table 2 and the wafers pass through the third space D, however, the first purge gas is directly sprayed thereto, so that the temperature of the rotary table 2 and the wafer may change due to the cooling effect. Since the adsorption and reaction of the first reactant gas and the second reactant gas depend on substrate temperature, the above-noted temperature change results in the adsorption and reaction being not performed homogeneously over the extent of the substrate surface. A homogeneous thin film thus cannot be formed.

In consideration of this, the heating units 8 are used to heat the first purge gas to a temperature sufficiently close to the temperature of the rotary table 2 and the wafers that are heated by the heater unit 7. The heated first purge gas is discharged from the first purge gas supply units 41 and 42. As a result, when the rotary table 2 and the wafers pass through the third space D, cooling does not occur despite the fact that the first purge gas is directly sprayed, thereby preventing the temperature fluctuation of the rotary table 2 and the wafer. Thus, the adsorption and reaction of the first reactant gas and the second reactant gas are performed evenly over the extent of the substrate surface, thereby successfully forming a homogeneous thin film.

In the following, a description will be given of members that are situated outside the outer circumference of the rotary table 2, below the rotary table 2, and above the bottom section 14, among various elements contained in the vacuum container 1. Namely, the container 12 and an exhaust space 6 will be described.

As illustrated in FIG. 7, the inner wall of the container 12 is formed vertically in the close proximity of the outer circumferential surface of the bent part 46 at the angular position of the third space D. At the other angular positions where the third space D is not situated, the inner wall of the container 12 has a recess that appears in FIG. 1 as a step-like-shape dent in the cross-sectional view of the container 12 from the position facing the side edge of the rotary table 2 down to the position immediately above the bottom section 14. This recess constitutes an exhaust space 6.

At the bottom of the exhaust space 6 are provided two exhaust outlets 61 and 62 as illustrated in FIG. 1 and FIG. 3, for example. The exhaust outlets 61 and 62 are connected through exhaust pipes 63 to a common vacuum pump 64 serving as a vacuum exhaust unit A pressure adjustment unit 65 is provided for the exhaust pipe 63 between the exhaust outlet 61 and the vacuum pump 64. The pressure adjustment unit 65 may be provided for each of the exhaust outlets 61 and 62, or may be provided as a single common unit. The exhaust outlets 61 and 62 may preferably be situated on both sides of the third space D such as to allow the third space D to effectively serve its isolation function. The exhaust outlets 61 and 62 serve to exhaust the first reactant gas and the second reactant gas, respectively. In the present embodiment, the exhaust outlet 61 is disposed between the first reactant gas supply unit 31 and the third space D adjoining the space of the first reactant gas supply unit 31 downstream in the rotation direction. The exhaust outlet 62 is disposed between the second reactant gas supply unit 32 and the third space D adjoining the space of the second reactant gas supply unit 32 downstream in the rotation direction.

The number of exhaust outlets is not limited to two. For example, another exhaust outlet may be disposed between the third space D including the first purge gas supply unit 42 and the second reactant gas supply unit 32 whose space adjoins this third space D downstream in the rotation direction. The number of exhaust outlets may even be four or more. In the illustrated example, the exhaust outlets 61 and 62 are situated in the bottom section 14 of the vacuum container 1 at the position lower than the rotary table 2. Exhaustion is thus conducted through a gap between the inner wall of the vacuum container 1 and the side edge of the rotary table 2. The positions of the exhaust outlets 61 and 62 are not limited to the bottom section 14 of the vacuum container 1. The exhaust outlets 61 and 62 may alternatively be formed in the sidewall of the vacuum container 1. When the exhaust outlets 61 and 62 are formed in the sidewall of the vacuum container 1, their position may be situated higher than the rotary table 2. With these arrangements of the exhaust outlets 61 and 62, the gases on the rotary table 2 flow toward the periphery of the rotary table 2. These arrangements are thus advantageous in that the unsettling of particles is reduced compared with the arrangement in which exhaustion is performed from above the rotary table 2.

In the following, a description will be given of portions situated below the rotary table 2 including the bottom section 14 of the vacuum container 1, among various portions contained in the vacuum container 1. Namely, a description will be given of the heater unit 7, a cover member 71, the bottom section 14, a third purge gas supply unit 72, and a fourth purge gas supply unit 73.

The heater unit 7 is disposed in a space between the rotary table 2 and the bottom section 14 of the vacuum container 1 as illustrated in FIG. 1 and FIG. 5. The heater unit 7 heats the wafers on the rotary table 2 through the rotary table 2 to a temperature that is determined according to the process recipes. The heater unit 7 may be situated above the rotary table 2, rather than situated below the rotary table 2, or may be situated above and below the rotary table 2. The heater unit 7 is not limited to the use of a resistance heating element, and may use an infrared lamp. A reflector may be provided on the lower half of the heater unit 7 to reflect the heat downwardly generated by the heater unit 7, thereby directing the heat upward to improve thermal efficiency.

The temperature of the rotary table 2 heated by the heater unit 7 is measured by a thermocouple embedded in the bottom section 14 of the vacuum container 1. The temperature measured by the thermocouple is transmitted to a control unit 100. The control unit 100 then controls the heater unit 7 to keep the temperature of the rotary table 2 to a predetermined temperature.

The cover member 71 is disposed under the rotary table 2 near its outer circumference. The cover member 71 serves to partition a space under the rotary table 2 from the exhaust space 6. Provision is made such that the cover member 71 covers the heater unit 7 along its entire circumference. The upper end of the cover member 71 is bent outward to form a flange portion. A gap between the flange portion and the lower surface of the rotary table 2 is set to be small, so that the first reactant gas and the second reactant gas do not enter the inner space of the cover member 71 to end up being mixed with each other.

The bottom section 14 has a raised structure that comes close to the lower surface of the rotary table 2 and the core 21 around the rotation center in the area that is inside the position of the heater unit 7. The through-hole formed through the bottom section 14 to accommodate the rotation shaft 22 is configured such that a gap between the rotation shaft 22 and the inner circumferential surface of the through-hole is narrow. The through-hole communicates with the case 20.

The third purge gas supply unit 72 is attached to the case 20. The third purge gas supply unit 72 serves to supply a third purge gas to a narrow space. Although the third purge gas is not limited to any particular gas, N2 gas may be used.

The fourth purge gas supply units 73 are disposed in the bottom section 14 of the vacuum container 1 at plural locations on a circumference under the heater unit 7. The fourth purge gas supply unit 73 serves to supply a fourth purge gas to the space in which the heater unit 7 is situated. Although the fourth purge gas is not limited to any particular gas, N2 gas may be used.

The flows of the third purge gas and the fourth purge gas are illustrated as arrows in FIG. 9. The third purge gas supply unit 72 and the fourth purge gas supply unit 73 supply N2 gas to the case 20 and the space in which the heater unit 7 is disposed. The N2 gas flows through the gap between the rotary table 2 and the cover member 71 into the exhaust space 6 for exhaustion through the exhaust outlets 61 and 62. With this arrangement, the first reactant gas and the second reactant gas are prevented from flowing from one of the first space P1 and the second space P2 to the other through the space situated under the rotary table 2. In this manner, the third purge gas serves as a purge gas. Further, the above-noted arrangement prevents the first reactant gas and the second reactant gas from flowing from the first space P1 and the second space P2 into the space in which the heater unit 7 is situated under the rotary table 2. Accordingly, the fourth purge gas also serves to prevent the first reactant gas and the second reactant gas from being adsorbed to the heater unit 7.

In the following, a description will be given of portions provided outside the vacuum container 1 and portions provided for conveyance purposes.

As illustrated in FIG. 2, FIG. 3, and FIG. 10, a loading port 15 is provided to allow a delivery arm 10 to load and unload a wafer to and from the rotary table 2. The loading port 15 is opened and closed by a gate valve (not shown). The recesses 24 serving as substrate placement parts on the rotary table 2 receive wafers W from and pass the wafers W to the delivery arm 10 at the position of the loading port 15. A mechanism that raises a wafer by pressing its lower surface with elevation pins 16 penetrating through the recess 24 is provided under the rotary table 2 at the position of the loading port 15.

The film deposition apparatus according to the present embodiment is provided with the control unit 100 implemented by use of a computer for the purpose of controlling the overall operation of the apparatus as illustrated in FIG. 1 and FIG. 3. As illustrated in FIG. 11, the control unit 100 includes a process controller 100a having a CPU for controlling various parts of the film deposition apparatus, a user interface unit 100b, and a memory unit 100c.

The user interface unit 100b includes a keyboard that may be used by a process administrator to enter command inputs for the purpose of controlling the film deposition apparatus, and also includes a display unit for displaying the visualized operating statuses of the film deposition apparatus.

The memory unit 100c stores recipes in which control programs (software), processing condition data, and the like are defined for the purpose of causing the process controller 100a to control various processes performed in the film deposition apparatus. As a need arises, an instruction given through the user interface unit 100b causes any selected recipes to be read from the memory unit 100c for execution by the process controller 100a, thereby causing the film deposition apparatus to perform desired processes under the control of the process controller 100a. Recipes such as control programs and processing condition data may be stored in a computer-readable program recording medium (e.g., a hard-disk drive, a compact-disc, a magneto-optical disc, a memory card, a floppy disc, etc.), and may be installed to the process controller 100a at the time of use. Alternatively, these recipes may be obtained from another apparatus by using dedicated lines for transmission, for example, to be used on line each time such a need arises.

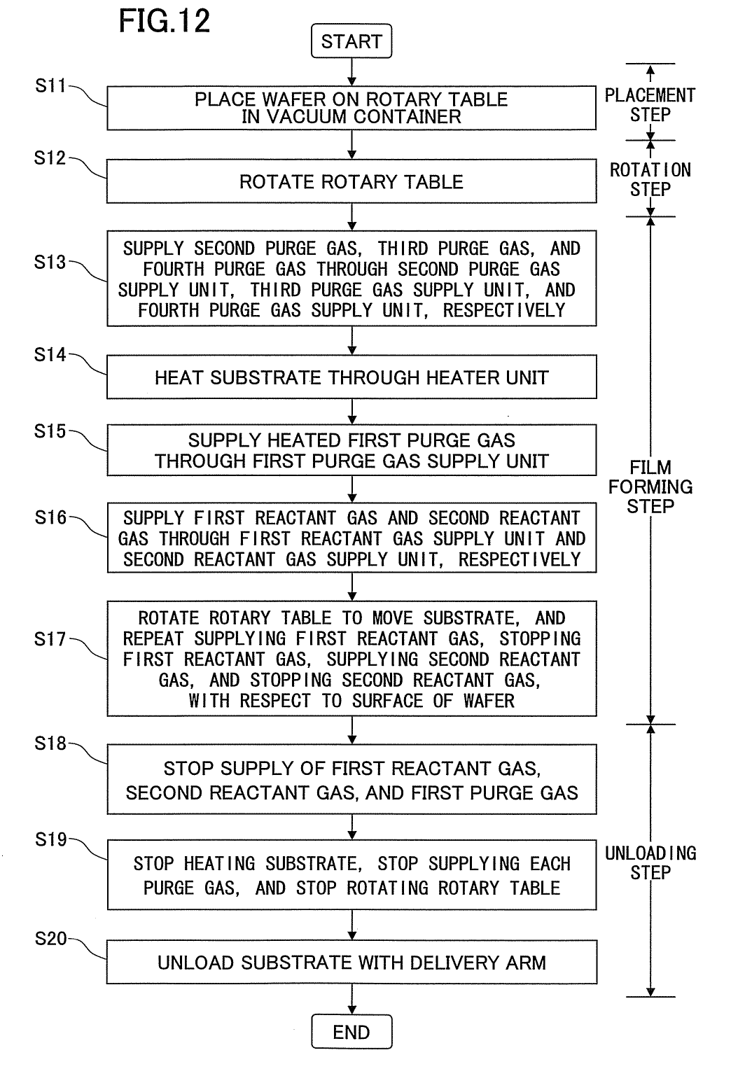

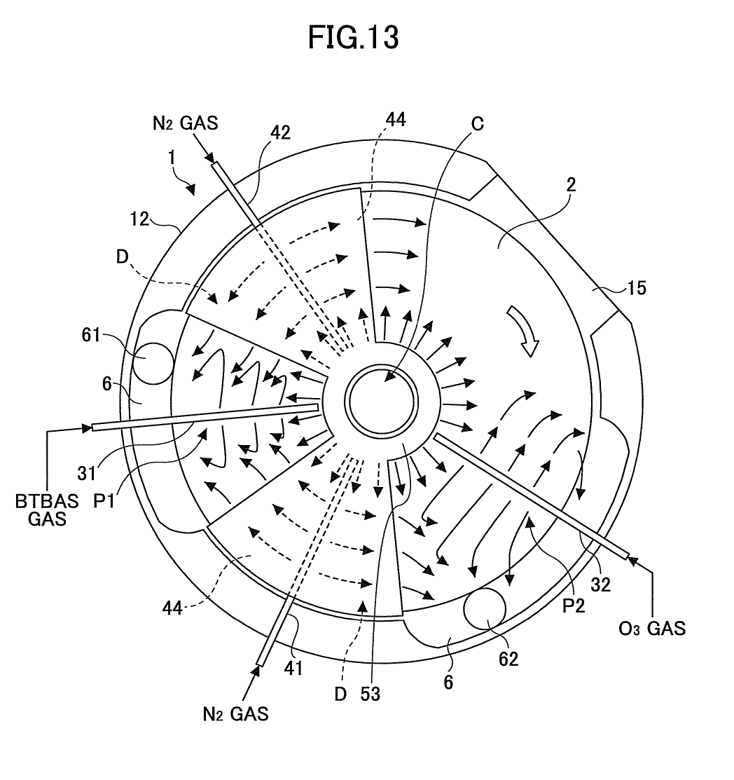

In the following, a description will be given of a method of forming a film by use of the film deposition apparatus according to the present embodiment by referring to FIG. 10, FIG. 12, and FIG. 13.

FIG. 12 is a flowchart illustrating the steps of the method of forming a film by use of the film deposition apparatus according to the present embodiment. FIG. 13 is a drawing illustrating the method of forming a film by use of the film deposition apparatus according to the present embodiment, with illustration of the flows of the first reactant gas, the second reactant gas, and the first purge gas. Similarly to FIG. 3, FIG. 13 illustrates a view that would be obtained by horizontally cutting the top panel 11 of the vacuum container 1 at a height lower than the first lower surface part 45 and the second lower surface part 45a and higher than the first purge gas supply units 41 and 42.

As illustrated in FIG. 12, the method of forming a film according to the present embodiment includes a placement step for placing a wafer on the rotary table in the vacuum container, a rotation step for rotating the rotary table, a film forming step, and an unloading step. In the film forming step, the rotary table is heated from below, and the first reactant gas supply unit and the second reactant gas supply unit supply the first reactant gas and the second reactant gas, respectively. Further, the first purge gas supply units supply the first purge gas that is heated. The rotation of the rotary table 2 serves to move the wafers. A thin film is formed by repeating the supply of the first reactant gas, the stoppage of supply of the first reactant gas, the supply of the second reactant gas, and the stoppage of supply of the second reactant gas, with respect to the surface of each wafer. In the unloading step, the supply of the first reactant gas, the second reactant gas, and the first purge gas is stopped, and the heating of the substrates is stopped. Further, the supply of each protection gas is stopped, and the rotation of the rotary table is stopped. Then, the wafers are unloaded by the delivery arm 10.

The placement step is performed first. As illustrated in step S11 of FIG. 12, the placement step places wafers on the rotary table in the vacuum container.

Specifically, as illustrated in FIG. 10, the gate valve is opened, and the external delivery arm 10 loads the wafer W onto the recess 24 of the rotary table 2. The loading is performed by moving the elevation pins 16 extending from the bottom side of the vacuum container through the holes penetrating the bottom surface of the recess 24 when the recess 24 comes to and stops at the position of the loading port 15, as illustrated in FIG. 10. The loading of a wafer W is performed while rotating the rotary table 2 intermittently, so that wafers W are placed on all the five recesses 24 of the rotary table 2.

The rotation step is then performed. As illustrated in step S12 of FIG. 12, the rotation step rotates the rotary table 2.

The film forming step is then performed. As illustrated in step S13 through step S17 of FIG. 12, the film forming step includes the following steps. In step S13, the second purge gas supply unit, the third purge gas supply unit, and the fourth purge gas supply unit supply the second purge gas, the third purge gas, and the fourth purge gas, respectively. In step S14, the heater unit heats the substrates. In step S15, the first purge gas supply units supply the heated first purge gas. In step S16, the first reactant gas supply unit 31 and the second reactant gas supply unit 32 supply the first reactant gas and the second reactant gas, respectively. In step S17, the rotary table 2 is rotated to move the substrates, and a thin film is formed by repeating the supply of the first reactant gas, the stoppage of supply of the first reactant gas, the supply of the second reactant gas, and the stoppage of supply of the second reactant gas, with respect to the surface of each wafer.

In step S13, the vacuum pump 64 depressurizes the inner space of the vacuum container 1 to a predetermined pressure, and, then, the second purge gas supply unit 51, the third purge gas supply unit 72, and the fourth purge gas supply unit 73 supply the second purge gas, the third purge gasp and the fourth purge gas, respectively.

In step S14, the heater unit heats the substrates W. In this step, the heater unit 7 heats the wafers W to 300 degrees Celsius after the wafers W are placed on the rotary table 2. Alternatively, the heater unit 7 may heat the rotary table 2 to 300 degrees Celsius in advance, followed by placing the wafers W on the heated rotary table 2 to heat the wafers W.

In step S15, the first purge gas supply units supply the heated first purge gas. Namely, the first purge gas heated by the heating units 8 is supplied, and the temperature sensor is utilized to confirm that the temperature of the wafers W is kept at the predetermined temperature. Such a check may be performed by using a radiation thermometer situated under the rotary table 2.

In step S16, the first reactant gas supply unit 31 and the second reactant gas supply unit 32 supply the first reactant gas and the second reactant gas, respectively. Namely, the first reactant gas supply unit 31 and the second reactant gas supply unit 32 discharge BTBAS gas and O3 gas, respectively. This is done while using the temperature sensor to ensure that the temperature of the substrates W is kept at the predetermined temperature. Such a measurement may be made by using a radiation thermometer situated under the rotary table 2.

It should be noted that steps S13, S14, S15, and S16 do not have to be performed in the sequence as described, and may be performed in a different sequence. They may even be performed at the same time. For example, the sequence may be arranged such that while the first reactant gas supply unit 31 and the second reactant gas supply unit 32 discharge BTBAS gas and O3 gas, respectively, the first purge gas supply units 41 and 42 discharge N2 gas serving as the first purge gas.

The steps S13 through S16 are performed as described above, so that the rotary table 2 is rotated to move the substrates, and a thin film is formed by repeating the supply of the first reactant gas, the stoppage of supply of the first reactant gas, the supply of the second reactant gas, and the stoppage of supply of the second reactant gas, with respect to the surface of each wafer, as defined in step S17.

Each of the wafers W passes alternately through the first space P1 including the first reactant gas supply unit 31 and the second space P2 including the second reactant gas supply unit 32 due to the rotation of the rotary table 2. The BTBAS gas is adsorbed, and, then, the O3 gas is adsorbed, so that the BTBAS molecules are oxidized to form one or more molecule layers of silicon oxide. Through such a process, silicon oxide molecule layers are formed one over another to form a silicon oxide film having a predetermined thickness.

In so doing, the second purge gas supply unit 51 also supplies N2 gas serving as a purge gas. As a result, the N2 gas is discharged from the center area C through the gap between the projection 53 and the center portion of the rotary table 2 to flow over the surface of the rotary table 2. In the disclosed example, the inner wall of the vacuum container 1 has recesses to provide wider spaces at the angular position of the first lower surface part 45 including the position of the first reactant gas supply unit 31 and the at the angular position of the second lower surface part 45a including the position of the second reactant gas supply unit 32. The exhaust outlets 61 and 62 are formed at the bottom of these wider spaces. Accordingly, pressures inside the spaces under the first lower surface part 45 and the second lower surface part 45a are lower than pressures inside the narrow spaces under the third lower surface part 44 and within the center area C. One of the reasons why the pressures inside the spaces under the first lower surface part 45 and the second lower surface part 45a are lower than pressures inside the spaces under the third lower surface part 44 and within the center area C is as follows. Namely, the narrow space under the third lower surface part 44 is configured such that the third height H3 keeps a pressure difference between this narrow space and the first space P1 (or second space P2), i.e., between the narrow space and the space in which the first reactant gas supply unit 31 (or second reactant gas supply unit 32) is situated.

FIG. 13 illustrates the flows of gases that are discharged from the respective units. O3 gas is discharged downwardly from the second reactant gas supply unit 32. The O3 gas comes in contact with the surface of the rotary table 2 (i.e., the surfaces of the wafers W placed in the recesses 24, the recesses 24 where no wafer W is placed, and the surface of the rotary table 2 other than the areas of the recesses 24), and partly flows upstream in the rotation direction over the surface of the rotary table 2. This O3 gas is pushed back by the N2 gas flowing from upstream in the rotation direction to enter the exhaust space 6 by passing through the gap between the side edge of the rotary table 2 and the inner circumferential wall of the vacuum container 1 for exhaustion through the exhaust outlet 62.

Further, the O3 gas discharged downwardly from the second reactant gas supply unit 32 comes in contact with the surface of the rotary table 2 to partially flow downstream in the rotation direction over the surface of the rotary table 2. This O3 gas is guided by the flow of the N2 gas discharged from the center area C and the sucking force of the exhaust outlet 62 in order to flow toward the exhaust outlet 62. Some of the O3 gas, however, goes toward the adjacent third space D situated downstream, and would possibly enter the area under the third lower surface part 44 having a fan shape. However, the height and circumferential length of the third lower surface part 44 are designed such that the intrusion of gas into the space under the third lower surface part 44 is prevented under the operating conditions corresponding to operating process parameters inclusive of the amount of gas flows. Accordingly, as illustrated in FIG. 13 and also in FIG. 4B, the O3 gas cannot flow into the space under the third lower surface part 44 having a fan shape. Even if the O3 gas enters this space, it cannot go near the first purge gas supply unit 41. The O3 gas is pushed back upstream in the rotation direction by the N2 gas discharged from the first purge gas supply unit 41 into the second space P2. As a result, this O3 gas, together with the N2 gas discharged from the center area C, enter the exhaust space 6 by passing through the gap between the side edge of the rotary table 2 and the inner circumferential wall of the vacuum container 1 for exhaustion through the exhaust outlet 62.

The BTBAS gas discharged downwardly from the first reactant gas supply unit 31 flows upward and downward in the rotation direction over the surface of the rotary table 2. The BTBAS gas cannot enter the spaces under the fan-shape third lower surface parts 44 situated upstream and downstream in the rotation direction. Even if the BTBAS gas enters these spaces, the BTBAS gas is pushed back toward the first space P1. The BTBAS gas together with the N2 gas discharged from the center area C flow into the exhaust space 6 for exhaustion through the exhaust outlet 61. Namely, each third space D prevents the intrusion of the BTBAS gas and O3 gas serving as reactant gases in the atmosphere, whereas the gas molecules adsorbed to the wafers pass through the isolation area, i.e., through the space under the fan-shape third lower surface part 44, thereby contributing to the film formation.

Moreover, the BTBAS gas in the first space P1 and the O3 gas in the second space P2 would possibly enter the center area C. As illustrated in FIG. 9 and FIG. 13, however, the second purge gas is discharged from the center area C towards the periphery of the rotary table 2. This second purge gas thus prevents the intrusion of the O3 gas. Even if the O3 gas finds its way into the center area C, the O3 gas is pushed back. In this manner, the O3 gas is prevented from entering the first space P1 or the second space P2 through the intervening center area C.

In the third space D, the fan-shape periphery edge of the top panel 11 is bent downward, so that the gap between the bent part 46 and the side surface of the rotary table 2 is very narrow, thereby substantially preventing the passage of gases. Accordingly, the BTBAS gas in the first space P1 (or O3 gas in the second space P2) is prevented from entering the second space P2 (or the first space P1) by going through the periphery space of the rotary table 2. The two third spaces D thus completely isolate the atmosphere of the first space P1 and the atmosphere of the second space P2 from each other, so that the BTBAS gas is exhausted through the exhaust outlet 61, and the O3 gas is exhausted through the exhaust outlet 62. In this manner, the first reactant gas BTBAS and the second reactant gas O3 are not mixed at all in the atmosphere or over the wafer. In this example, further, N2 gas serving as the second purge gas is supplied to the space under the rotary table 2. With this arrangement, gases entering the exhaust space 6 do not go through the space under the rotary table 2. For example, the second reactant gas BTBAS does not flow into the space in which the second reactant gas O3 is discharged.

The unloading step is performed after the film forming step. As illustrated in step S18 through step S20 of FIG. 12, the unloading step includes the following steps. In step S11, the supply of the first reactant gas, the second reactant gas, and the first purge gas is stopped. In step S19, the heating of the substrates is stopped, and the supply of the second purge gas, the third purge gas, and the fourth purge gas is stopped. The rotation of the rotary table 2 is also stopped. In step S20, the delivery arm 10 unloads the wafers through the loading port 15.

In the following, an example of process parameters will be described. The rate of revolution of the rotary table 2 may be 1 rpm to 300 rpm when the wafer W subjected to processing has a diameter of 300 mm. The process pressure may be 1067 Pa (i.e., 8 Torr). The temperature of the heated wafer W may be 350 degrees Celsius. The flow amounts of BTBAS gas and O3 gas may be 100 sccm and 10000 sccm, respectively. The flow amount of N2 gas through the first purge gas supply units 41 and 42 may be 20000 sccm. The flow amount of N2 gas through the second purge gas supply unit 51 at the center portion of the vacuum container 1 may be 5000 sccm. The number of cycles of reactant gas supply with respect to one wafer, i.e., the number of times the wafer passes through each of the first space P1 and the second space P2, may vary according to a desired film thickness. An example of a typical number may be 600.

In the present embodiment, plural wafers W are arranged in a circular direction of the rotary table 2. The rotary table 2 is rotated to cause the wafers W to pass through the first space P1 and the second space P2 in sequence, thereby performing the ALD (or MLD). This achieves a film deposition process with high throughput. The third space D having a low ceiling is disposed between the first space P1 and the second space P2 in the circular direction. Further, a purge gas is discharged from the center area C towards the periphery of the rotary table 2 wherein the center area C is partitioned by the rotation center portion of the rotary table 2 and the vacuum container 1. Moreover, the purge gas dispersing into both sides of the third space D, the purge gas discharged from the center area C, and the reactant gases are exhausted through the space between the inner circumferential wall of the vacuum container 1 and the side edge of the rotary table 2. This arrangement successfully prevents the mixing of the reactant gases, thereby achieving a satisfactory film deposition process. Further, the generation of reaction products over the rotary table 2 is prevented or significantly suppressed, so that the generation of particles is suppressed. It should be noted that the rotary table 2 may be configured to have only one wafer W placed thereon.

Applied process gases may include, in addition to the examples described heretofore, DSC (Dichlorosilane), HCD (Hexachlorodisilane), TMA (Trimethylaluminium), 3DMAS (Trisdimethylaminosilane), TEMAZ (Tetrakisethylmethylaminozirconium), TEMAH (Tetrakisethylmethylamidohafnium), Sr(THD)2 (Strontium bis-tetramethylheptanedionate), Ti(MPD(THD)2 (titanium methylpentanedionatobistetramethylheptanedionato), and monoaminosilane.

As described heretofore, the film deposition apparatus according to the present embodiment achieves high throughput. The film deposition apparatus according to the present embodiment also performs a satisfactory process by preventing plural reactant gases from being mixed over the substrates, and prevents the substrates from being cooled by a purge gas thereby to form a homogeneous thin film.

The film deposition apparatus according to the present embodiment is directed to an example in which two types of reactant gases are used. The present invention is not limited to the use of two types of reactant gases, and is also applicable to the configuration in which three or more types of reactant gases are supplied to a substrate in sequence. For example, a first reactant gas, a second reactant gas, and a third reactant gas may be used as three types of reactant gases. In this case, a first reactant gas supply unit, a first purge gas supply unit, a second reactant gas supply unit, a first purge gas supply unit, a third reactant gas supply unit, and a first purge gas supply unit may be arranged in a circular direction in the vacuum container 1 in the order listed, with the lower surface of the top panel 11 being sectioned into areas including the respective gas supply units.

### First Variation of First Embodiment

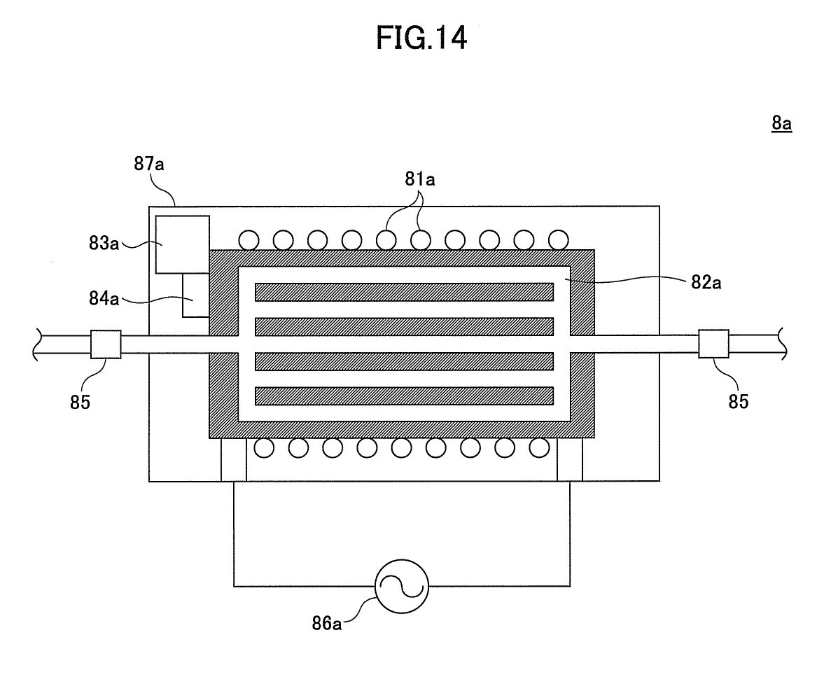

In the following, a description will be given of a film deposition apparatus according to a first variation of the first embodiment by referring to FIG. 14.

FIG. 14 is a drawing schematically illustrating the configuration of a heater of the film deposition apparatus according to the present variation. In the following description, the same elements as those previously described are referred to by the same numerals, and a description thereof may be omitted. The same applies to the subsequent variations and embodiments.

The film deposition apparatus according to the present variation differs from the film deposition apparatus of the first embodiment in that the heating mechanism used in the heating unit for heating the first purge gas and the second purge gas utilizes a high-frequency induction heating method.

Referring to FIG. 14, a heating unit 8a used in this variation utilizes a high-frequency induction heating method, which is different from the resistance heating method used in the heating unit of the first embodiment such as a sheathed heater or carbon heater.

As illustrated in FIG. 14, the heating unit 8a includes a heater 81a, a heating pipe 82a, a thermo switch 83a, a temperature sensor 84a, a joint 85a, an external power supply 86a, and a base 87a.

The heater 81a is a coil for use in the high-frequency induction heating method. This coil is not limited to any particular type. A copper-wire coil may be used in this variation.

The heating pipe 82a is one or more pipes formed through an electrically-conductive and thermally-conductive metal member that is surrounded by the coil of the heater 81a. The heating pipe 82a is induction-heated by the heater 81a while having the first purge gas flowing inside its interior space, thereby exchanging heat with the first purge gas to heat the first purge gas. The heating pipe 82a is not limited to any particular structure. For example, the heating pipe 82a may be implemented by use of a honeycomb-structure SUS.

The thermo switch 83a, the temperature sensor 84a, and the external power supply 86a serve to function as follows. The thermo switch 83a switches between the ON state and the OFF state in response to a difference between a preset temperature and a temperature measured by the temperature sensor 84a. The external power supply 36a supplies power to the heater 81a to perform induction heating when the thermo switch 83a is in the ON state. The external power supply 86a is an AC power supply.

The heating unit 8a as described above is used to heat the first purge gas. When the first purge gas supply units supply the first purge gas, thus, the cooling of temperature of the rotary table 2 and the substrates placed on the rotary table 2 is avoided.

In the present variation, the heating unit 8a is situated outside the vacuum container 1. The position of the heating unit 8a is not limited to outside the vacuum container 1 as long as the first purge gas and second purge gas can be heated and supplied through the first purge gas supply units 41 and 42. Provision may be made such that the heating unit 8a is situated inside the vacuum container 1.

In the present variation, the heating units 8a may be provided at two separate locations corresponding to the first purge gas supply units 41 and 42, respectively. The heating units 8a may be positioned at the same location as long as the first purge gas and second purge gas can be heated and supplied through the first purge gas supply units 41 and 42.

### Second Variation of First Embodiment

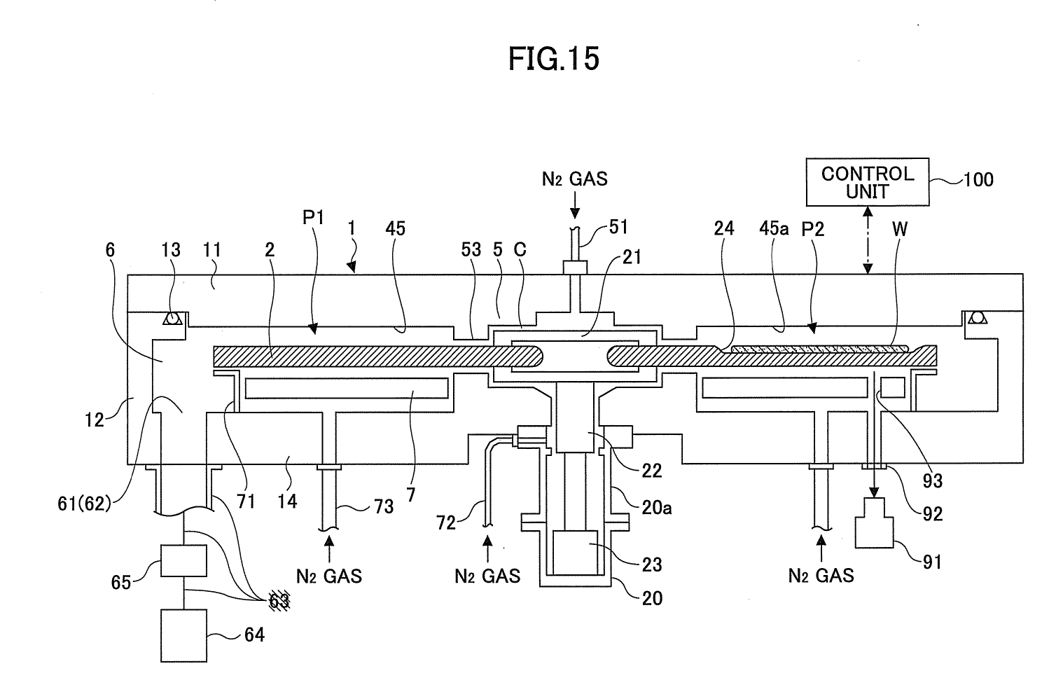

In the following, a description will be given of a film deposition apparatus according to a second variation of the first embodiment by referring to FIG. 15.

FIG. 15 is a longitudinal sectional view schematically illustrating a film deposition apparatus according to the present variation.

The film deposition apparatus according to the present variation differs from the film deposition apparatus of the first embodiment in that a radiation thermometer is used to measure the temperature of the rotary table.

Referring to FIG. 15, a radiation thermometer 91 is used to directly measure the temperature of the rotary table 2 in the present variation, which is different from the first embodiment in which the thermocouple is embedded into the vacuum container near the rotary table to measure the temperature of the rotary table at some distance from the rotary table.

The bottom section 14 of the vacuum container 1 has a transparent window 92, which allows infrared light generated by the rotary table 2 inside the vacuum container 1 to be detected from under the vacuum container 1. Further, the heater unit 7 has a through-hole 93 formed at the position corresponding to the position of the transparent window 92 formed through the bottom section 14, thereby allowing infrared light generated by the rotary table 2 to be detected. Further, the radiation thermometer 91 is positioned outside the vacuum container 1 at the position corresponding to the position of the transparent window 92 to detect the infrared light generated by the rotary table 2 for temperature measurement.

With this arrangement, the temperature of the rotary table 2 is measured by use of the radiation thermometer 91, so that temperature variation can be more accurately detected than in the case in which the temperature is measured by use of a thermocouple. Accordingly, temperature is more accurately monitored when the heated first purge gas is sprayed to the rotary table 2 under the third lower surface part 44. This can enhance the effect of suppressing changes in the temperature of the rotary table 2 based on the use of the heated first purge gas.

Data indicative of the temperature of the rotary table 2 measured by the radiation thermometer 91 may be sent to the control unit 100, which then controls the heating units 8 accordingly. With this arrangement, such control may be possible that the temperature of the rotary table 2 does not exhibit any change even when the first purge gas is sprayed. This can further enhance the effect of suppressing changes in the temperature of the rotary table 2 based on the use of the heated first purge gas.

### Third Variation of First Embodiment

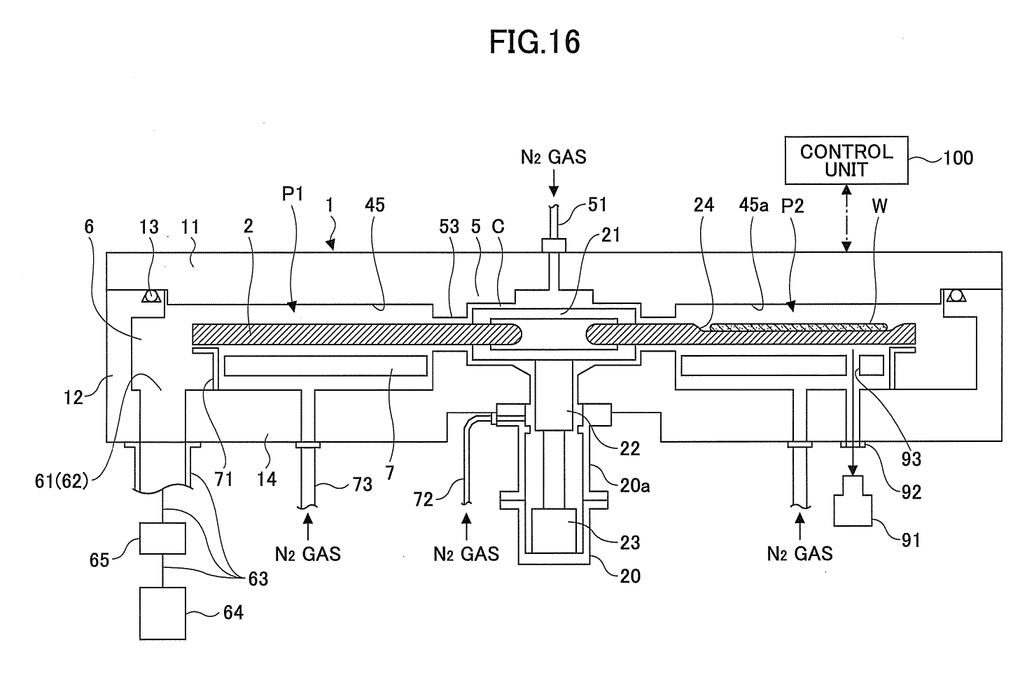

In the following, a description will be given of a film deposition apparatus according to a third variation of the first embodiment by referring to FIG. 16.

FIG. 16 is a longitudinal sectional view schematically illustrating a film deposition apparatus according to the present variation.

The film deposition apparatus according to the present variation differs from the film deposition apparatus of the first embodiment in that the rotary table is made of quartz.

Referring to FIG. 16, the rotary table 2 used in this variation is made of quartz, which is different from the second variation of the first embodiment in which the rotary table is made or carbon.

The bottom section 14 of the vacuum container 1 has the window 92, and the heater unit 7 has the through-hole 93. Further, the radiation thermometer 91 is situated outside the vacuum container 1. These arrangements are the same as in the second variation of the first embodiment.

In the present variation, the rotary table 2 is made of quartz. Quartz allows the passage of infrared light. The radiation thermometer can thus directly measure the temperature of a substrate from under the rotary table 2. Accordingly, substrate temperature is more accurately monitored when the heated first purge gas is sprayed to the rotary table 2 under the third lower surface part 44. This can enhance the effect of suppressing changes in the substrate temperature based on the use of the heated first purge gas.

Data indicative of the substrate temperature measured by the radiation thermometer 91 may be sent to the control unit 100, which then controls the heating units 8 accordingly. With this arrangement, such control may be possible that the substrate temperature does not exhibit any change even when the first purge gas is sprayed. This can further enhance the effect of suppressing changes in the substrate temperature based on the use of the heated first purge gas.

The material of the rotary table 2 used in the present variation is not limited to quartz. As long as the material does not contaminate substrates and other members provided inside the vacuum container 1, any material that transmits infrared light may be used.

### Fourth Variation of First Embodiment

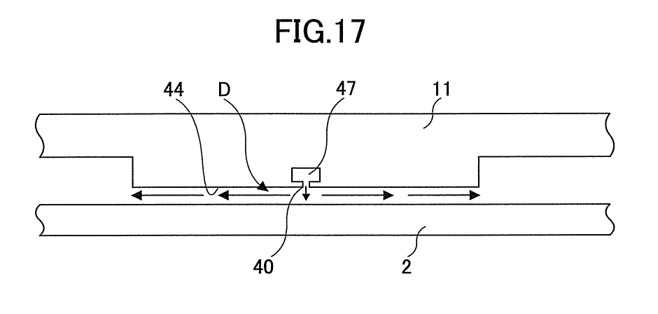

In the following, a description will be given of a film deposition apparatus according to a fourth variation of the first embodiment by referring to FIG. 17.

FIG. 17 is a longitudinal sectional view illustrating another example of the shape of the top panel at the third lower surface part in the film deposition apparatus according to the present variation.

The film deposition apparatus according to the present variation differs from the film deposition apparatus of the first embodiment in that a conduit 47 for conducting the first purge gas is formed inside the top panel 11 at an angular position corresponding to the third space D to extend radially with respect to the rotation center of the rotary table 2.

Referring to FIG. 17, the present variation differs from the first embodiment in which a groove is formed at the angular position of the first purge gas supply unit, such that the third lower surface part has two portions sandwiching the first purge gas supply unit. In the present variation, the conduit 47 for conducting the first purge gas is formed inside the top panel 11 of the vacuum container 1 radially with respect to the center of the rotary table 2 at an angular position corresponding to the third space D, with a plurality of gas discharge ports 40 being formed at the bottom of the conduit 47 along its longitudinal extension.

There is thus no need to provide a first purge gas supply unit in addition to the conduit 47, thereby reducing the number of components while achieving the same functions as those attained by the first embodiment.

### Fifth Variation of First Embodiment

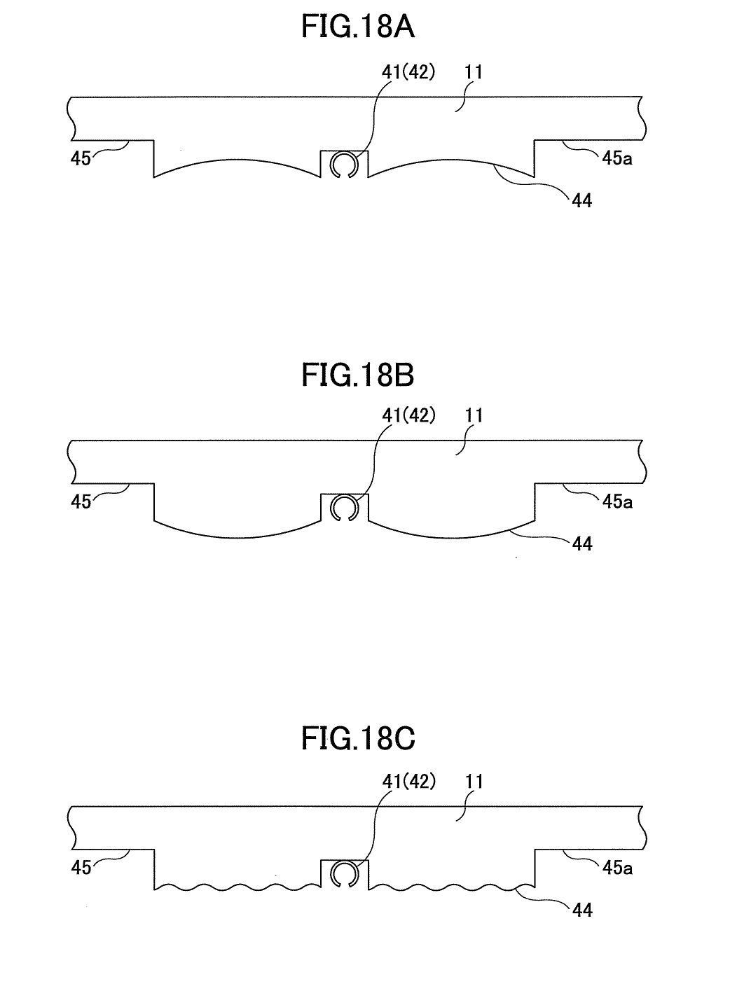

In the following, a description will be given of a film deposition apparatus according to a fifth variation of the first embodiment by referring to FIGS. 18A through 18C.

FIGS. 18A through 18C are longitudinal sectional views illustrating other examples of the shape of the top panel at the third lower surface part in the film deposition apparatus according to the present variation.

The film deposition apparatus according to the present variation differs from the film deposition apparatus of the first embodiment in that the third lower surface part over the third space D has a curved surface.

Referring to FIGS. 18A through 18C, the present variation differs from the first embodiment in which the third lower surface part has flat surfaces on both sides of a first purge gas supply unit. In the present variation, the third lower surface part 44 has curved surfaces on both sides of the first purge gas supply unit 41.

The third lower surface part 44 is not limited to the flat surface configuration as used in the first embodiment as long as it can exert the function to insolate the first reactant gas and the second reactant gas from each other. The third lower surface part 44 may have concave surfaces as illustrated in FIG. 18A, convex surfaces as illustrated in FIG. 18B, or wave-shape surfaces as illustrated in FIG. 18C. When the third lower surface part 44 has concave surfaces as illustrated in FIG. 18A, for example, the height of the third lower surface part 44 relative to the rotary table 2 is reduced at the edges of the third lower surface part 44 adjoining the first lower surface part 45 and the second lower surface part 45a, respectively. This configuration prevents the intrusion of the first reactant gas and the second reactant gas into the third lower surface part 44 more effectively. When the third lower surface part 44 has convex surfaces as illustrated in FIG. 18B, for example, the height of the third lower surface part 44 relative to the rotary table 2 is reduced at the peaks of the convex surfaces. This configuration prevents the intrusion of the first reactant gas and the second reactant gas into the third lower surface part 44 more effectively. The configuration in which the third lower surface part 44 has wavy surfaces as illustrated in FIG. 18C is equivalent to providing a plurality of convex-surface peaks compared to the configuration illustrated in FIG. 18B. This configuration prevents the intrusion of the first reactant gas and the second reactant gas into the third lower surface part 44 more effectively.

The third lower surface part 44 may be the lower surface of the top panel 11. Alternatively, the third lower surface part 44 may be implemented by use of a member separate from the top panel 11 to be attached to the top panel 11.

### Sixth Variation of First Embodiment

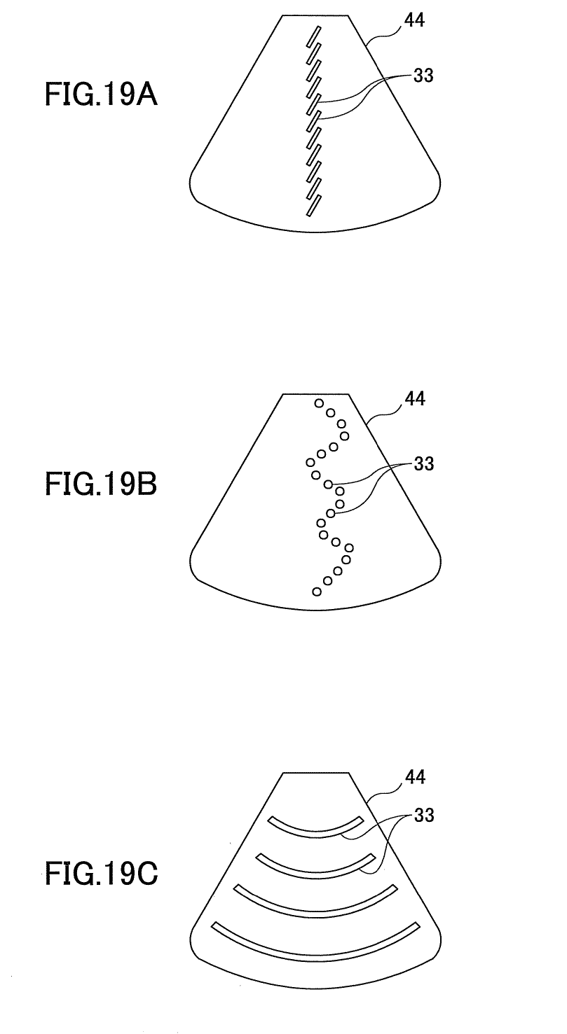

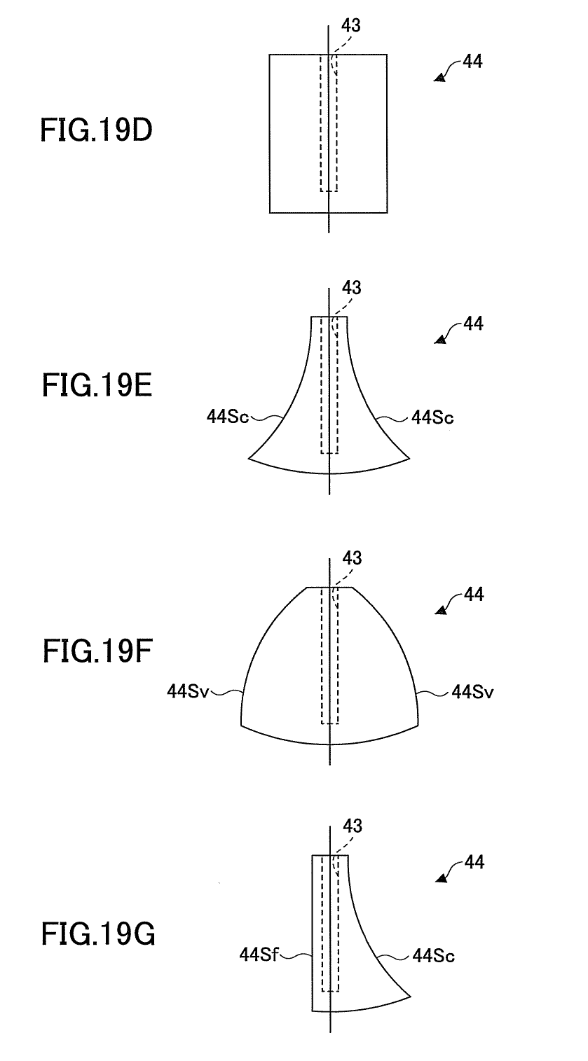

In the following, a description will be given of a film deposition apparatus according to a sixth variation of the first embodiment by referring to FIGS. 19A through 19C.

FIGS. 19A through 19C are base views illustrating examples of gas discharge ports of the first purge gas supply unit of the film deposition apparatus according to the present variation. FIGS. 19D through 19G are base views illustrating examples of the shape of the third lower surface part of the film deposition apparatus according to the present variation. In FIGS. 19A through 19C, the third lower surface part 44 and the positions of the spouts 33 are illustrated.

The film deposition apparatus according to the present variation differs from the film deposition apparatus of the first embodiment in that the spouts formed in the first purge gas supply unit are not formed along a straight line extending radially with respect to the rotation center of the rotary table 2.

Referring to FIGS. 19A through 19C, the present variation differs from the first embodiment in which the spouts 33 formed in the first purge gas supply unit are arranged along a straight line extending radially with respect to the rotation center of the rotary table 2. In the present variation, the spouts 33 are not arranged along a straight line extending radially with respect to the rotation center of the rotary table 2.

The arrangement of the spouts 33 is not limited to the straight-line arrangement extending radially with respect to the rotation center of the rotary table 2 as in the first embodiment. The spouts (i.e., discharge ports) may have the following arrangements as long as they can supply the first purge gas evenly to substrates.

As illustrated in FIG. 19A, the spouts 33 may each have a slit shape (i.e., rectangular shape) oriented at an angle to the radius of the rotary table 2, and may be arranged at constant intervals in the radial direction. As illustrated in FIG. 19B, the spouts 33 having a circular shape may be arranged along a serpentine path. As illustrated in FIG. 19C, the spouts 33 having an arc shape may be arranged in a concentric manner with respect to the rotation center of the rotary table 2.

The third lower surface part 44 may be configured to be hollow, so that the first purge gas fills the hollow space. In such a case, the spouts 33 may be configured as illustrated in FIG. 19A, FIG. 19B, and FIG. 19C.

In the present variation, the third lower surface part 44 has a fan shape in a plan view. Alternatively, the third lower surface part 44 may be configured to have a rectangular shape as illustrated in FIG. 19D or square shape in a plan view. The third lower surface part 44 may have a generally fan shape, with curved concave side edges 44Sc, as illustrated in FIG. 19E. The third lower surface part 44 may have a generally fan shape, with curved convex side edges 44Sv, as illustrated in FIG. 19F. As illustrated in FIG. 19G, the third lower surface part 44 may be configured such that its side edge situated on the upstream side in the rotation direction of the rotary table 2 is a concave edge 44Sc, and its side edge situated on the downstream side in the rotation direction of the rotary table 2 is a straight edge 44Sf. In FIG. 19D through FIG. 19G, dotted lines represent a groove part 43 (see also FIG. 4A and FIG. 4B) formed in the third lower surface part 44. In these cases, the first purge gas supply units 41 and 42 (see FIG. 2) accommodated in the respective groove parts 43 may extend from the center portion of the vacuum container 1, e.g., extend from the projection 53 (see FIG. 1).

With the above-noted arrangements of the spouts 33, the first purge gas is more evenly distributed under the third lower surface part 44. This configuration prevents the intrusion of the first reactant gas and the second reactant gas into the third lower surface part 44 more effectively.

### Seventh Variation of First Embodiment

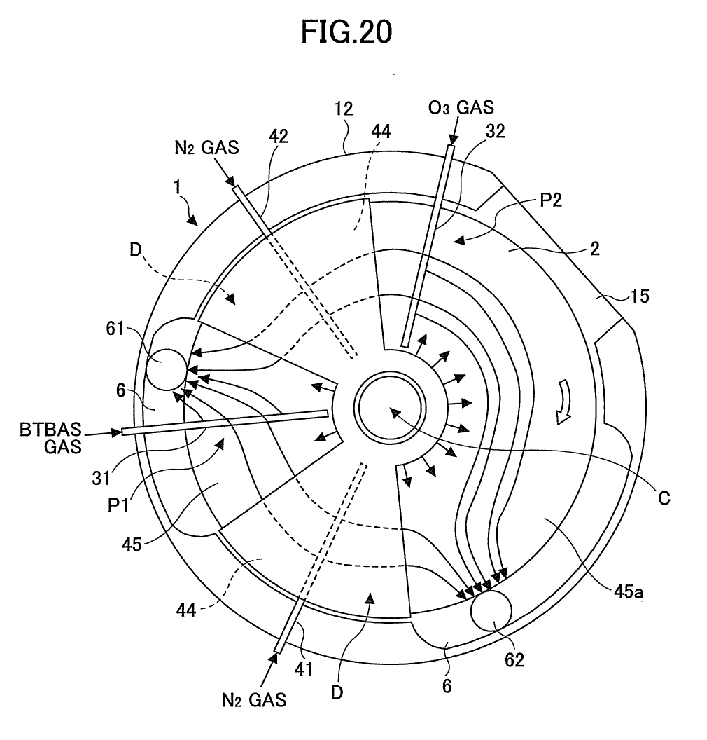

In the following, a description will be given of a film deposition apparatus according to a seventh variation of the first embodiment by referring to FIG. 20.

FIG. 20 is a transverse sectional view schematically illustrating the configuration of a film deposition apparatus according to the present variation. In other words, FIG. 20 is a plan view of the vacuum container 1 from which the top panel 11 is removed.

The film deposition apparatus according to the present variation differs from the film deposition apparatus of the first embodiment in that the second reactant gas supply unit is situated on the upstream side of the loading port in the rotation direction of the rotary table.

Referring to FIG. 20, the present variation differs from the first embodiment in which the second reactant gas supply unit is situated on the downstream side of the loading port in the rotation direction of the rotary table. In the present variation, the second reactant gas supply unit 32 is situated on the upstream side of the loading port 15 in the rotation direction of the rotary table 2.

Even with such a layout, the first reactant gas and the second reactant gas can be efficiently isolated from each other. Also, the first purge gas may be prevented from spreading into the space under the second lower surface part 45a. Accordingly, the first reactant gas and the second reactant gas may effectively be supplied to the wafers in the first lower surface part 45 and the second lower surface part 45a, respectively.

### Eighth Variation of First Embodiment

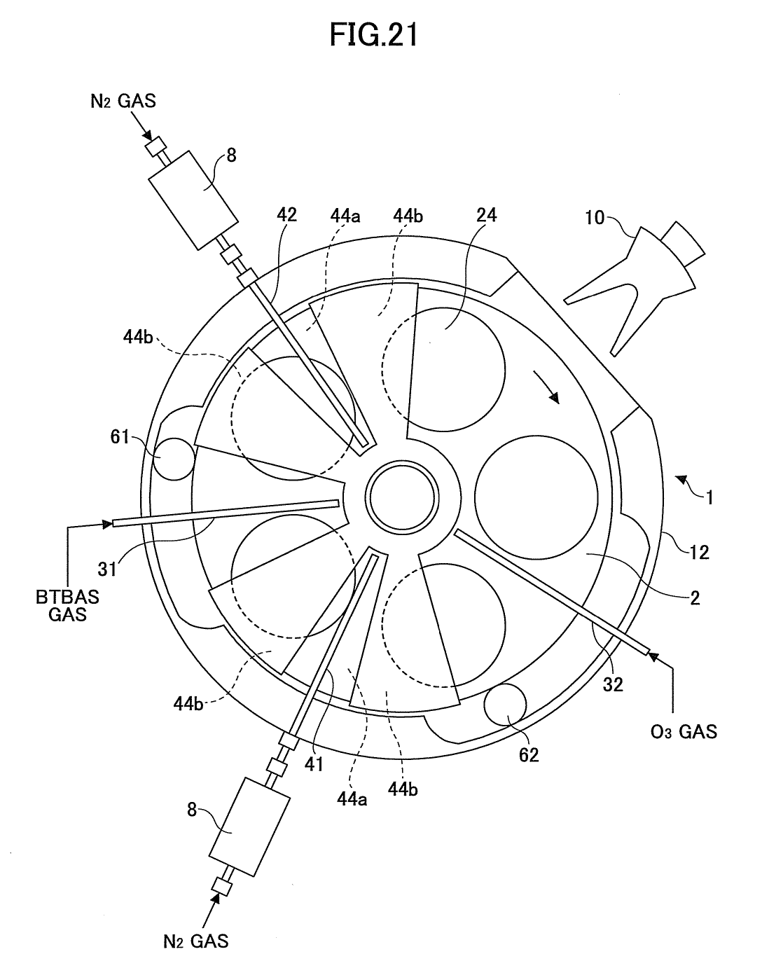

In the following, a description will be given of a film deposition apparatus according to an eighth variation of the first embodiment by referring to FIG. 21.

FIG. 21 is a transverse sectional view schematically illustrating the configuration of a film deposition apparatus according to the present variation. FIG. 21 illustrates a view that would be obtained by horizontally cutting the top panel 11 of the vacuum container 1 at a height lower than the first lower surface part 45 and the second lower surface part 45a and higher than the first purge gas supply units 41 and 42.

The film deposition apparatus according to the present variation differs from the film deposition apparatus of the first embodiment in that the third lower surface part 44 is divided into two portions arranged in a circular direction, between which is situated the first purge gas supply unit.

Referring to FIG. 21, the present variation differs from the first embodiment in which the lower surface of the top panel has the same height relative to the rotary table at any position on the third lower surface part. In the present variation, third lower surface parts 44a covering the positions of the first purge gas supply units 41 and 42 have a height higher than the third height H3 as measured from the rotary table 2. Third lower surface parts 44b adjoin one of the third lower surface parts 44a, and have the third height H3 relative to the rotary table 2.

With the provision of these parts, the first reactant gas and the second reactant gas can be efficiently isolated from each other, and, also, the first purge gas may be prevented from spreading into the spaces under the first lower surface part 45 and the second lower surface part 45a. Accordingly, the first reactant gas and the second reactant gas may effectively be supplied to the wafers in the first lower surface part 45 and the second lower surface part 45a, respectively.

The distances between the third lower surface parts 44b and the first purge gas supply units 41 and 42 as well as the shape and size of the third lower surface parts 44b may be optimally designed by taking into account the discharge flow amounts of the first reactant gas, the second reactant gas, and the first purge gas.

### Ninth Variation of First Embodiment

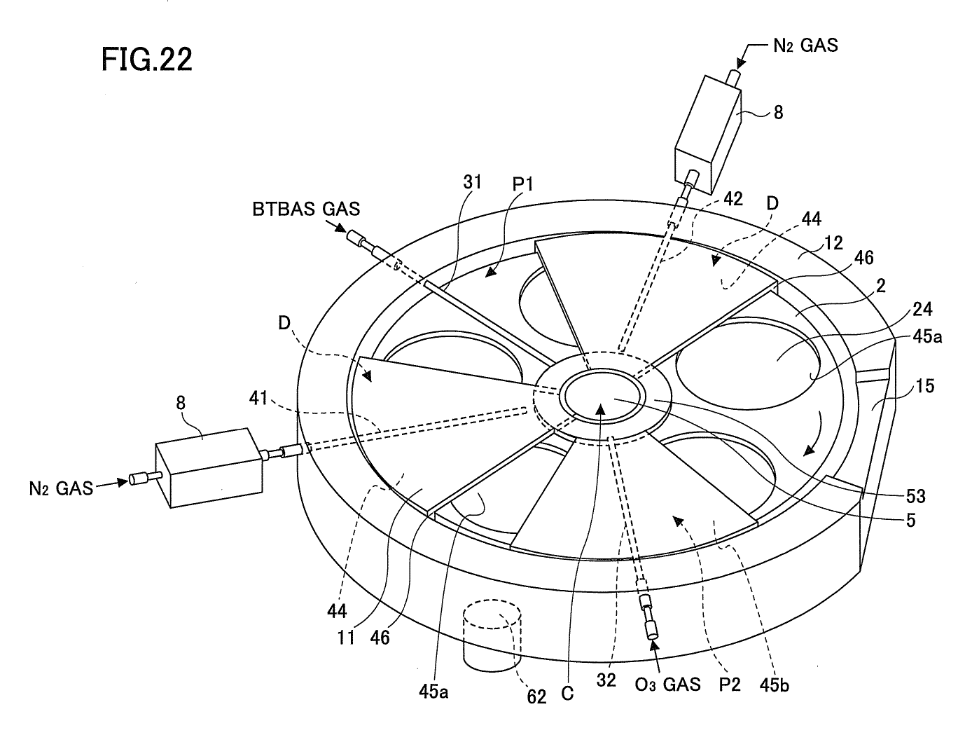

In the following, a description will be given of a film deposition apparatus according to a ninth variation of the first embodiment by referring to FIG. 22.

FIG. 22 is an oblique perspective view schematically illustrating the configuration of a film deposition apparatus according to the present variation.

The film deposition apparatus according to the present variation differs from the film deposition apparatus of the first embodiment in that a sixth lower surface part and a seventh lower surface part are provided in place of the second lower surface part.

Referring to FIG. 22, the present variation differs from the first embodiment in which the lower surface of the top panel of the vacuum container 1 has the same height relative to the rotary table at any position on the second lower surface part. In the present variation, a sixth lower surface part 45b and a seventh lower surface part 45a are provided in place of the second lower surface part. The sixth lower surface part 45b covers the position of the second reactant gas supply unit 32, and has a height lower than the second height H2 as measured from the rotary table 2. The seventh lower surface part 45a adjoins the sixth lower surface part 45b, and has the second height H2 relative to the rotary table 2.

The sixth lower surface part 45b is the same as the third lower surface part 44, except that it covers the position of the second reactant gas supply unit 32 rather than the first purge gas supply units 41 and 42.

With the provision of the sixth lower surface part 45b, the first reactant gas and the second reactant gas can be efficiently isolated from each other, and, also, the first purge gas may be prevented from spreading into the space under the sixth lower surface part 45b. Accordingly, the second reactant gas is more efficiently supplied to wafers under the sixth lower surface part 45b.

The sixth lower surface part 45b may be formed substantially in the same manner as the third lower surface part 44 having a hollow structure as illustrated in FIG. 19A through 19C as examples.

In the present variation, the sixth lower surface part and the seventh lower surface part are provided in place of the second lower surface part. Further, a fourth lower surface part and a fifth lower surface part may be provided in place of the first lower surface part. The fourth lower surface part covers the position of the first reactant gas supply unit, and has a height lower than the first height H1 as measured from the rotary table. The fifth lower surface part adjoins the fourth lower surface part, and has the first height H1 relative to the rotary table. The provision of such a fourth lower surface part also efficiently isolates the first reactant gas and the second reactant gas from each other. Further, the intrusion of the first purge gas into the space under the fourth lower surface part is also prevented. Accordingly, the first reactant gas is more efficiently supplied to wafers under the fourth lower surface part.

### Tenth Variation of First Embodiment

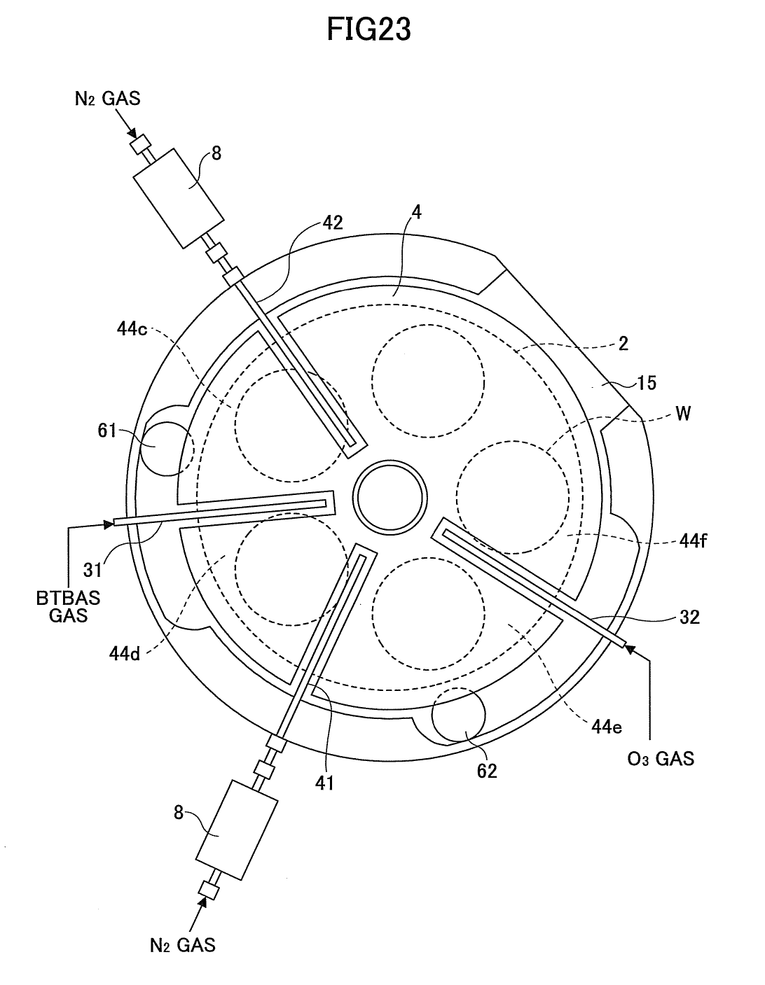

In the following, a description will be given of a film deposition apparatus according to a tenth variation of the first embodiment by referring to FIG. 23.

FIG. 23 is a transverse sectional view schematically illustrating the configuration of a film deposition apparatus according to the present variation. In other words, FIG. 23 is a plan view of the vacuum container from which the top panel is removed.

The film deposition apparatus according to the present variation differs from the film deposition apparatus of the first embodiment in that lower ceilings are provided on both sides of each of the first reactant gas supply unit and the second reactant gas supply unit.

Referring to FIG. 23, the present variation differs from the first embodiment in which the third lower surface parts having lower ceiling surfaces than the first lower surface part and the second lower surface part are provided for the purpose of forming narrow spaces around the first purge gas supply units. In the present variation, third lower surface parts 44c through 44f having the same low ceilings as the third lower surface part 44 are formed around the first reactant gas supply unit 31 and the second reactant gas supply unit 32, and these third lower surface parts 44c through 44f constitute a continuous structure.

As illustrated in FIG. 23, the third lower surface part(s) is formed over the entire area of the rotary table 2, except for the narrow strips where the first purge gas supply units 41 and 42, the first reactant gas supply unit 31, and the second reactant gas supply unit 32 are situated. In other words, the third lower surface parts 44 as originally provided in the first embodiment for the first purge gas supply units 41 and 42 are now extended to the areas where the first reactant gas supply unit 31 and the second reactant gas supply unit 32 are situated. In this configuration, the first purge gas spreads to both sides of the first purge gas supply unit 41 (42), and the first reactant gas and the second reactant gas spread to both sides of the first reactant gas supply unit 31 and the second reactant gas supply unit 32, respectively. The purge gas and reactant gas meet with each other in the space (i.e., narrow space) between the third lower surface parts 44c through 44f and the rotary table 2. These gases are exhausted through the exhaust outlet 61 (62) situated between the first (second) reactant gas supply unit 31 (32) and the first purge gas supply unit 42 (41). The present variation provides substantially the same results as those of the first embodiment.

The third lower surface parts 44c through 44f may be implemented by combining different hollow structures illustrated in FIG. 19A through 19C. Instead of using the first reactant gas supply unit 31, the second reactant gas supply unit 32, and the first purge gas supply units 41 and 42, the first reactant gas, the second reactant gas, and the purge gas may be discharged from the spouts 33 formed on the lower surfaces of the third lower surface parts 44c through 44f that are hollow.

### Eleventh Variation of First Embodiment

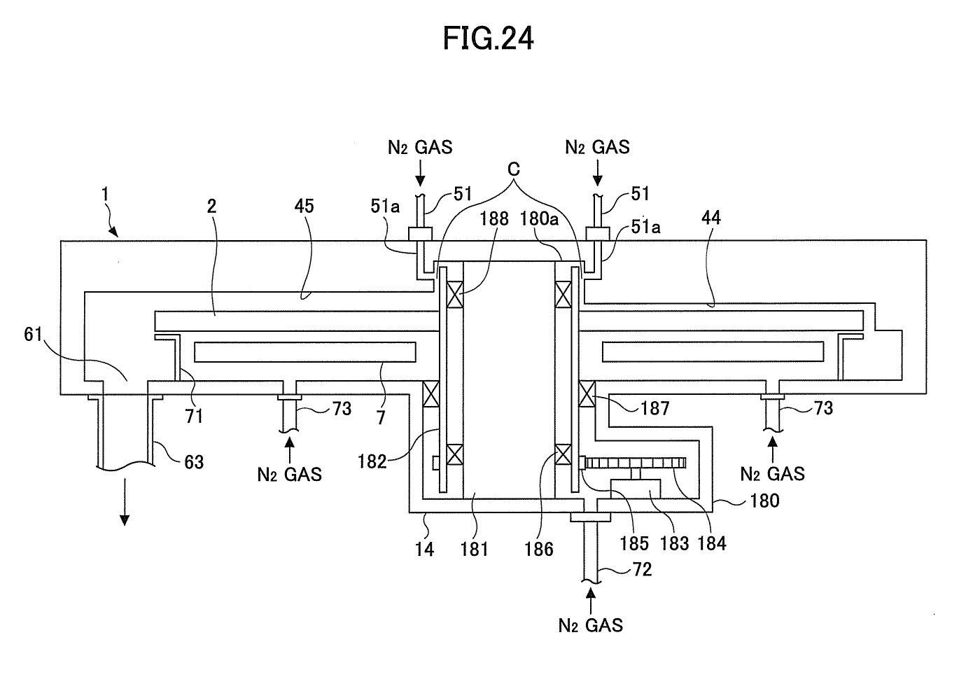

In the following, a description will be given of a film deposition apparatus according to an eleventh variation of the first embodiment by referring to FIG. 24.

FIG. 24 is a longitudinal sectional view schematically illustrating the configuration of a film deposition apparatus according to the present variation.

The film deposition apparatus according to the present variation differs from the film deposition apparatus of the first embodiment in that a pillar structure is provided at the center of the vacuum container from the bottom section to the top panel thereby to prevent the mixing of reactant gases.

Referring to FIG. 24, the present variation differs from the first embodiment in which the rotation shaft of the rotary table is provided at the center of the vacuum container, with a purge gas being discharged into the space between the top panel and the center area of the rotary table. In the present variation, a recess 180a is formed in the top plate at the center area of the vacuum container 1, and a pillar structure 181 is provided at the center area of the vacuum container 1 from the bottom section of a container space 180 to the upper end of the recess 180a.

As illustrated in FIG. 24, the bottom section 14 bulges downward at the center area of the vacuum container 1 to form the container space 180, and the recess 180a is formed in the top plate at the center area of the vacuum container 1. Further, the pillar structure 181 is situated at the center area of the vacuum container 1 from the bottom section of the container space 180 to the upper end of the recess 180a. This arrangement prevents BTBAS gas from the first reactant gas supply unit 31 and O3 gas from the second reactant gas supply unit 32 from being mixed with each other through the center area of the vacuum container 1.

In order to rotate the rotary table 2, a rotary sleeve 182 is disposed to surround the pillar structure 181. The rotary table 2 has a ring shape and is fixedly attached to the rotary sleeve 182. A drive cog 184 driven by a motor 183 is placed inside the container space 180. This drive cog 184 rotates the rotary sleeve 182. Bearings 186, 187, and 188 are provided for the rotary sleeve 182. The third purge gas supply unit 72 for supplying the third purge gas is connected to the bottom of the container space 180. The second purge gas supply units 51 are connected to the top portion of the vacuum container 1 to supply the second purge gas to a gap between the sidewall of the recess 180a and the top portion of the rotary sleeve 182. In FIG. 24, orifices 51a for conducting the second purge gas to the gap between the sidewall of the recess 80a and the top portion of the rotary sleeve 182 are provided at two locations. It is preferable to determine the number of orifices 51a (i.e., the number of second purge gas supply units 51) by taking into account the effectiveness of the mechanism for preventing BTBAS gas and O3 gas from being mixed with each other through the area around the rotary sleeve 182.

In the configuration illustrated in FIG. 24, the gap between the sidewall of the recess 80a and the top portion of the rotary sleeve 182 serves as a purge gas discharge port as viewed from the rotary table 2. This purge gas discharge port, the rotary sleeve 182, and the pillar structure 181 constitute the center area C situated at the center of the vacuum container 1.

### Second Embodiment

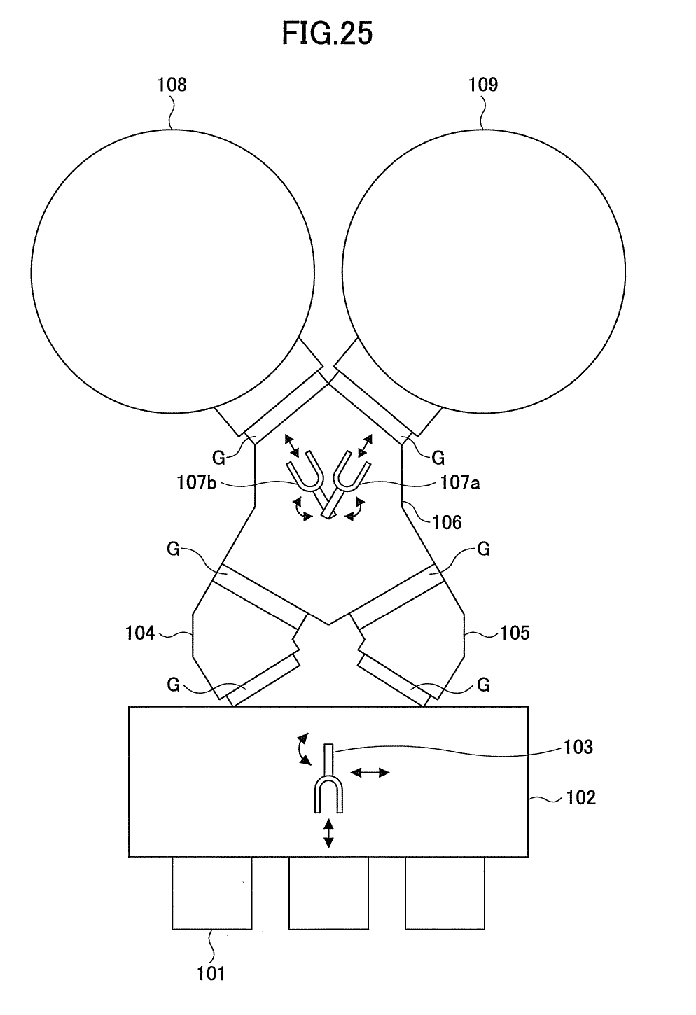

In the following, a description will be given of a substrate processing apparatus according to a second embodiment by referring to FIG. 25.

FIG. 25 is a plan view illustrating the configuration of the substrate processing apparatus according to the present embodiment.

As illustrated in FIG. 25, the substrate processing apparatus according to the present embodiment includes a delivery container 101, an atmosphere delivery chamber 102, a delivery arm 103, load lock chambers (vacuum preparation chamber) 104 and 105, a vacuum delivery chamber 106, delivery arms 107a and 107b, and film deposition apparatuses 108 and 109.

The delivery container 101 is a sealed-type container referred to as a “hoop” for containing 25 wafers, for example. The atmosphere delivery chamber 102 accommodates the delivery arm 103. The load lock chambers 104 and 105 can be switched between air atmosphere and vacuum atmosphere. The vacuum delivery chamber 106 accommodates two delivery arms 107a and 107b. Each of the film deposition apparatuses 108 and 109 is the film deposition apparatus according to the first embodiment.

The delivery container 101 is delivered from another place, and is placed at a loading/unloading port having a platform (not illustrated) After the delivery container 101 is placed, an opening/closing mechanism (not shown) opens the hatch of the atmosphere delivery chamber 102. The delivery arm 103 then takes wafers out of the delivery container 101. The wafers taken out of the delivery container 101 are conveyed to the load lock chamber 104 or 105. Then, the inner space of the load lock chamber 104 or 105 is changed from air atmosphere to vacuum atmosphere. The delivery arm 107a or 107b takes the wafers out of the load lock chamber 104 or 105, and delivers the wafers to the film deposition apparatus 108 or 109. Thereafter, the film deposition apparatus 108 or 109 performs the film deposition method as previously described to form films

In the present embodiment, two first-embodiment film deposition apparatuses each configured to process five wafers, for example, may be provided. The provision of plural film deposition apparatuses makes it possible to perform an ALD or MLD film forming process at high throughput.

In the present embodiment, the film deposition apparatuses 108 and 109 according to the first embodiment are used, so that the first purge gas is heated by the heating unit. Accordingly, the substrates are not cooled by the purge gas when the purge gas is supplied from the first reactant gas supply unit, thereby maintaining the substrate temperature to form a homogeneous thin film.

Further, the present invention is not limited to these embodiments, but various variations and modifications may be made without departing from the scope of the present invention.

The present application is based on Japanese priority application No. 2008-227027 filed on Sep. 4, 2008, with the Japanese Patent Office, the entire contents of which are hereby incorporated by reference.

What is claimed is:

1. A film deposition apparatus for forming a thin film by exposing a substrate to at least two types of reactant gases including a first reactant gas and a second reactant gas in sequence in a vacuum container, comprising:
a vacuum container having a top panel;
a rotary table configured to rotate around a rotation center in the vacuum container and having one or more substrate placement parts on which substrates are placed;
a first reactant gas supply unit and a second reactant gas supply unit extending radially at a first angular position and at a second angular position with respect to the rotation center, respectively, to supply the first reactant gas and the second reactant gas, respectively;
a first purge gas supply unit extending radially at a third angular position between the first angular position and the second angular position to supply a first purge gas for isolating the first reactant gas and the second reactant gas from each other;
a first lower surface area of the top panel situated at a first height from the rotary table to form a first space having the first height over the rotary table in at least part of an area that includes the first angular position;
a second lower surface area of the top panel situated at a second height from the rotary table to form a second space having the second height over the rotary table in at least part of an area that includes the second angular position;
a third lower surface area of the top panel situated at a third height from the rotary table to form a third space having the third height over the rotary table in at least part of an area that includes the third angular position, the third height being lower than the first height and the second height;
a heating unit configured to heat the first purge gas;
a second purge gas supply unit configured to supply a second purge gas to isolate the first reactant gas and the second reactant gas from each other in a center area including the rotation center; and
exhaust outlets, each configured to exhaust a corresponding one of the first reactant gas and the second reactant gas together with the first purge gas discharged from the third space and the second purge gas discharged from the center area.

2. The film deposition apparatus as claimed in claim 1, wherein the heating unit is situated outside the vacuum container.

3. The film deposition apparatus as claimed in claim 1, wherein the heating unit is configured to generate heat by resistance heating or high-frequency induction hating.

4. The film deposition apparatus as claimed in claim 1, further comprising a radiation thermometer disposed under the rotary table.

5. The film deposition apparatus as claimed in claim 1, wherein the rotary table is made of a transparent material.

6. The film deposition apparatus as claimed in claim 5, wherein the rotary table is made of quartz.

7. The film deposition apparatus as claimed in claim 1, further comprising a third purge gas supply unit configured to supply a third purge gas to isolate the first reactant gas and the second reactant gas from each other under the rotation center of the rotary table.

8. The film deposition apparatus as claimed in claim 1, further comprising a fourth purge gas supply unit configured to supply a fourth purge gas to isolate the first reactant gas and the second reactant gas from each other between a bottom part of the vacuum container and the rotary table.

9. The film deposition apparatus as claimed in claim 1, further comprising:
a pillar structure disposed between a lower surface of the top panel and a bottom surface of the vacuum container at the center area of the vacuum container; and
a rotary sleeve disposed around the pillar structure to be rotabable around a vertical axis
wherein the rotary sleeve serves as a rotary shaft for the rotary table.

10. The film deposition apparatus as claimed in claim 1, further comprising a fourth lower surface area of the top panel situated lower than the first height from the rotary table in at least part of the area that includes the first angular position, the fourth lower surface area adjoining the first lower surface area.

11. The film deposition apparatus as claimed in claim 1, further comprising a fifth lower surface area of the top panel situated lower than the second height from the rotary table in at least part of the area that includes the second angular position, the fifth lower surface area adjoining the second lower surface area.

12. The film deposition apparatus as claimed in claim 1, wherein an upper surface of the substrates placed on the substrate placement parts is situated at the same height as or lower than an upper surface of the rotary table.

13. The film deposition apparatus as claimed in claim 1, wherein the first reactant gas supply unit, the second reactant gas supply unit, and the first purge gas supply unit are configured to supply the first reactant gas, the second reactant gas, and the first purge gas, respectively, radially from inside to outside with respect to the rotation center of the rotary table or radially from outside to inside with respect to the rotation center of the rotary table.

14. The film deposition apparatus as claimed in claim 1, wherein the first purge gas supply unit has discharge spouts arranged radially with respect to the rotation center.

15. The film deposition apparatus as claimed in claim 14, wherein the third lower surface area is divided into two areas by a line of the discharge spouts, and an arc length of each of the two areas in a circular direction of the rotary table is 50 mm or longer at a point at which a center of the substrates placed on the substrate placement areas passes.

16. The film deposition apparatus as claimed in claim 1, wherein a lower surface of the top panel in the third lower surface area is either a flat surface of a curved surface.

17. The film deposition apparatus as claimed in claim 1, wherein the exhaust outlets include a first exhaust outlet and a second exhaust outlet that are formed in a periphery bottom surface of the vacuum container in a vicinity of the first space and the second space, respectively.

18. The film deposition apparatus as claimed in claim 1, wherein a pressure inside the third space is higher than a pressure inside the first space and a pressure inside the second space.

19. The film deposition apparatus as claimed in claim 1, further comprising a heating unit disposed under the rotary table to heat the rotary table.

20. The film deposition apparatus as claimed in claim 1, further comprising an loading port disposed on a side surface of the vacuum container to be opened and closed to allow the substrates to be loaded from and unloaded to outside the vacuum container.

21. The film deposition apparatus as claimed in claim 1, wherein the third lower surface area has a shape that increases in width towards a periphery of the rotary table

22. The film deposition apparatus as claimed in claim 1, wherein the third lower surface area has a fan shape in a plan view.

23. A substrate processing apparatus, comprising:
a film deposition apparatus of claim 1;
a vacuum delivery chamber hermetically coupled to the film deposition apparatus and includes a substrate delivery unit therein; and
a vacuum preparation chamber hermetically coupled to the vacuum delivery chamber and configured to be switchable between air atmosphere and vacuum atmosphere.

24. A film deposition method of forming a thin film on a substrate by exposing the substrate to at least two types of reactant gases including a first reactant gas and a second reactant gas in sequence in a vacuum container, in which a first purge gas supply area is provided to supply a first purge gas to isolate the first reactant gas and the second reactant gas from each other over a rotary table having the substrate placed thereon, and a height of a top panel of the vacuum container from an upper surface of the rotary table in the first purge gas supply area is lower than heights of the top panel in areas to which the first reactant gas and the second reactant gas are supplied, thereby to supply the first purge gas in a space having a relatively low height, and in which a second purge gas is supplied to an area around a rotation center of the rotary table at a lower surface of the top panel to isolate the first reactant gas and the second reactant gas from each, and each of the first reactant gas and the second reactant gas is exhausted together with the first purge gas and the second purge gas, so that the first reactant gas and the second reactant gas are supplied separately from each other to form a thin film, said method comprising the steps of:
a placement step of placing substrates on the rotary table inside the vacuum container;
a rotation step of rotating the rotary table; and
a film forming step of heating the rotary table from below, supplying the first reactant gas and the second reactant gas from a first reactant gas supply unit and a second reactant gas supply unit, respectively, situated at different angular positions with respect to a rotation center of the rotary table, supplying the first purge gas from a first purge gas supply unit situated between the first reactant gas supply unit and the second reactant gas supply unit after heating the first purge gas, and moving the substrates in association with the rotation of the rotary table thereby repeating supplying the first reactant gas, stopping the first reactant gas, supplying the second reactant gas, and stopping the second reactant gas with respect to a surface of the substrate to form a thin film.

25. The film deposition method as claimed in claim 24, wherein the thin film is formed while measuring a temperature of the rotary table or the substrate from under the rotary table by use of a radiation thermometer.

26. The film deposition method as claimed in claim 24, wherein the rotary table is made of a transparent material.

27. The film deposition method as claimed in claim 26, wherein the rotary table is made of quartz.

28. The film deposition method as claimed in claim 24, wherein a height of the top panel of the vacuum chamber from the upper surface of the rotary table in an area that includes the angular position of the first reactant gas supply unit in the area to which the first reactant gas is supplied is lower than a height of the top panel of the vacuum chamber from the upper surface of the rotary table in another part of the area to which the first reactant gas is supplied.

29. The film deposition method as claimed in claim 24, wherein a height of the top panel of the vacuum chamber from the upper surface of the rotary table in an area that includes the angular position of the second reactant gas supply unit in the area to which the second reactant gas is supplied is lower than a height of the top panel of the vacuum chamber from the upper surface of the rotary table in another part of the area to which the second reactant gas is supplied.

30. The film deposition method as claimed in claim 24, wherein the rotary table has a recess in which the substrate is placed, such that a surface of the substrate is at the same height as or lower than a surface of the rotary table.

31. The film deposition method as claimed in claim 24, wherein the film forming step is performed while heating the rotary table.

32. The film deposition method as claimed in claim 24, wherein the film forming step is performed while exhausting the first reactant gas and the second reactant gas through a first exhaust outlet and a second exhaust outlet, respectively, to outside the vacuum container.

33. A computer-readable record medium having a program recorded therein for causing a computer to perform the film deposition method of claim 24.
